(19) United States
(12) Patent Application Publication
(10) Pub. No.: US 2019/0036041 A1
(43) Pub. Date: Jan. 31, 2019

(54) Organometallic Iridium Complex, Light-Emitting Element, Light-Emitting Device, Electronic Device, Lighting Device, and Synthesis Method of Organometallic Iridium Complex

(71) Applicant: Semiconductor Energy Laboratory Co., Ltd., Kanagawa-ken (JP)

(72) Inventors: Hideko Inoue, Atsugi (JP); Tomoya Yamaguchi, Atsugi (JP); Satoshi Seo, Sagamihara (JP); Yui Yamada, Atsugi (JP)

(73) Assignee: Semiconductor Energy Laboratory Co., Ltd., Kanagawa-ken (JP)

(21) Appl. No.: 16/136,590

(22) Filed: Sep. 20, 2018

Related U.S. Application Data
(62) Division of application No. 14/924,114, filed on Oct. 27, 2015.

(30) Foreign Application Priority Data
Oct. 28, 2014 (JP) 2014-219055
Dec. 26, 2014 (JP) 2014-264848

(51) Int. Cl. H01L 51/00; C09K 11/06; C07F 15/00; H01L 51/50

(52) U.S. Cl. CPC H01L 51/0085; C09K 11/06; C07F 15/0033; H01L 51/0025; C09K 2211/1088; C09K 2211/1007; C09K 2211/185; H01L 51/5016; H01L 2251/5384; C09K 2211/1044

(57) ABSTRACT

A high-purity organometallic iridium complex is provided. The organometallic iridium complex includes iridium and a plurality of ligands cyclometallated to the iridium. Each of the plurality of ligands includes a heteroaromatic ring having a coordinatable nitrogen atom. In LC analysis of the organometallic iridium complex, an impurity which has a monochlorinated ligand among the plurality of ligands is 0.1% or less by quantitating using peak area count with a PDA detector.

This application is a divisional of copending U.S. application Ser. No. 14/924,114, filed on Oct. 27, 2015 which is incorporated herein by reference.

### BACKGROUND OF THE INVENTION

### 1. Field of the Invention

One embodiment of the present invention relates to an organometallic iridium complex and a synthesis method thereof. Specifically, one embodiment of the present invention relates to a high-purity organometallic iridium complex and a synthesis method thereof In addition, one embodiment of the present invention relates to a light-emitting element, a light-emitting device, an electronic device, and a lighting device each including the organometallic iridium complex. Note that one embodiment of the present invention is not limited to the above technical field. The technical field of one embodiment of the invention disclosed in this specification and the like relates to an object, a method, and a manufacturing method. In addition, one embodiment of the present invention relates to a process, a machine, manufacture, and a composition of matter.

### 2. Description of the Related Art

An organic EL element (light-emitting element) including an EL layer containing a light-emitting substance between a pair of electrodes has a light emission mechanism that is of a carrier injection type: a voltage is applied between the electrodes, electrons and holes injected from the electrodes recombine to put the light-emitting substance into an excited state, and then light is emitted in returning from the excited state to the ground state. The excited state can be a singlet excited state (S*) and a triplet excited state (T*). Light emission from a singlet excited state is referred to as fluorescence, and light emission from a triplet excited state is referred to as phosphorescence. The statistical generation ratio thereof in the light-emitting element is considered to be S*:T*=1:3.

Among the above light-emitting substances, a compound capable of converting singlet excitation energy into light emission is called a fluorescent compound (fluorescent material), and a compound capable of converting triplet excitation energy into light emission is called a phosphorescent compound (phosphorescent material).

Accordingly, the internal quantum efficiency (the ratio of the number of generated photons to the number of injected carriers) of a light-emitting element including a fluorescent material is thought to have a theoretical limit of 25%, on the basis of S*:T*=1:3, while the internal quantum efficiency of a light-emitting element including a phosphorescent material is thought to have a theoretical limit of 75%.

In other words, a light-emitting element including a phosphorescent material has higher efficiency than a light-emitting element including a fluorescent material. Thus, various kinds of phosphorescent materials have been actively developed in recent years. An organometallic complex that contains iridium or the like as a central metal is particularly attracting attention because of its high phosphorescence quantum yield (for example, see Patent Document 1 and Patent Document 2).

### REFERENCE

### Patent Document

[Patent Document 1] Japanese Published Patent Application No. 2007-137872
[Patent Document 2] Japanese Published Patent Application No. 2008-069221

### SUMMARY OF THE INVENTION

In a light-emitting element including an organometallic iridium complex, however, when the organometallic iridium complex contains a halogen-containing by-product generated during synthesis, an unreacted raw material, or the like, the element characteristics might be adversely affected. This suggests that low purity of the organometallic iridium complex causes large adverse effects on drive voltage, emission efficiency, and lifetime of the light-emitting element.

In view of the above, in one embodiment of the present invention, a synthesis method of a high-purity organometallic iridium complex is provided. A high-purity organometallic iridium complex is provided. A light-emitting element including the high-purity organometallic iridium complex and having low drive voltage is provided. A light-emitting device, an electronic device, or a lighting device that has low power consumption and has a long lifetime is provided.

One embodiment of the present invention is an organometallic iridium complex that includes iridium and a plurality of ligands cyclometallated to the iridium. Each of the plurality of ligands includes a heteroaromatic ring having a coordinatable nitrogen atom. In liquid chromatography (LC) analysis of the organometallic iridium complex, an organometallic iridium complex which has a monochlorinated ligand among the plurality of ligands is detected as an impurity at 0.1% or less by quantitating using peak area count with a photodiode array (PDA) detector.

Another embodiment of the present invention is an organometallic iridium complex that includes iridium and a plurality of ligands cyclometallated to the iridium. Each of the plurality of ligands includes a heteroaromatic ring which has a nitrogen atom coordinated to iridium. In LC-MS analysis of the organometallic iridium complex, an organometallic iridium complex is detected as an impurity concentration of 0.1% or less by quantitating using peak area count with a photodiode array (PDA) detector, and the impurity is observed at m/z=Mass number of the organometalllic iridium complex+35±1.[0011]

Another embodiment of the present invention is an organometallic iridium complex including a structure represented by General Formula (G2) below. In liquid chromatography (LC) analysis of the organometallic iridium complex, an organometallic iridium complex which has a monochlorinated ligand among the plurality of ligands is detected as an impurity concentration of 0.1% or less by quantitating using peak area count with a photodiode array (PDA) detector.

Another embodiment of the present invention is an organometallic iridium complex including the structure represented by General Formula (G2) below. In LC-MS analysis of the organometallic iridium complex, an organometallic iridium complex is detected as an impurity concentration of 0.1% or less by quantitating using peak area count with a PDA detector, and the impurity is observed at m/z=Mass number of the organometalllic iridium complex+35±1.

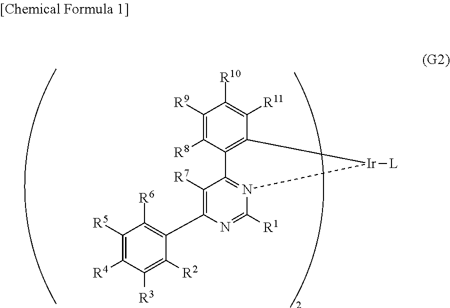

In General Formula (G2), each of R¹ to R¹¹ independently represents hydrogen or a substituted or unsubstituted alkyl group having 1 to 6 carbon atoms. L represents a monoanionic ligand.

In General Formula (G2), the monoanionic ligand is preferably a monoanionic bidentate chelate ligand having a β-diketone structure, a monoanionic bidentate chelate ligand having a carboxyl group, a monoanionic bidentate chelate ligand having a phenolic hydroxyl group, or a monoanionic bidentate chelate ligand in which two coordinating elements are both nitrogen. A monoanionic bidentate chelate ligand having a β-diketone structure is particularly preferable because the β-diketone structure allows the organometallic iridium complex to have higher solubility in an organic solvent and to be easily purified. The β-diketone structure is preferably included to obtain an organometallic iridium complex with high emission efficiency. Furthermore, the β-diketone structure brings advantages such as a higher sublimation property and excellent evaporativity.

The monoanionic ligand is preferably represented by any one of General Formulae (L1) to (L7). These ligands have high coordinative ability and can be obtained at low price, and are thus useful.

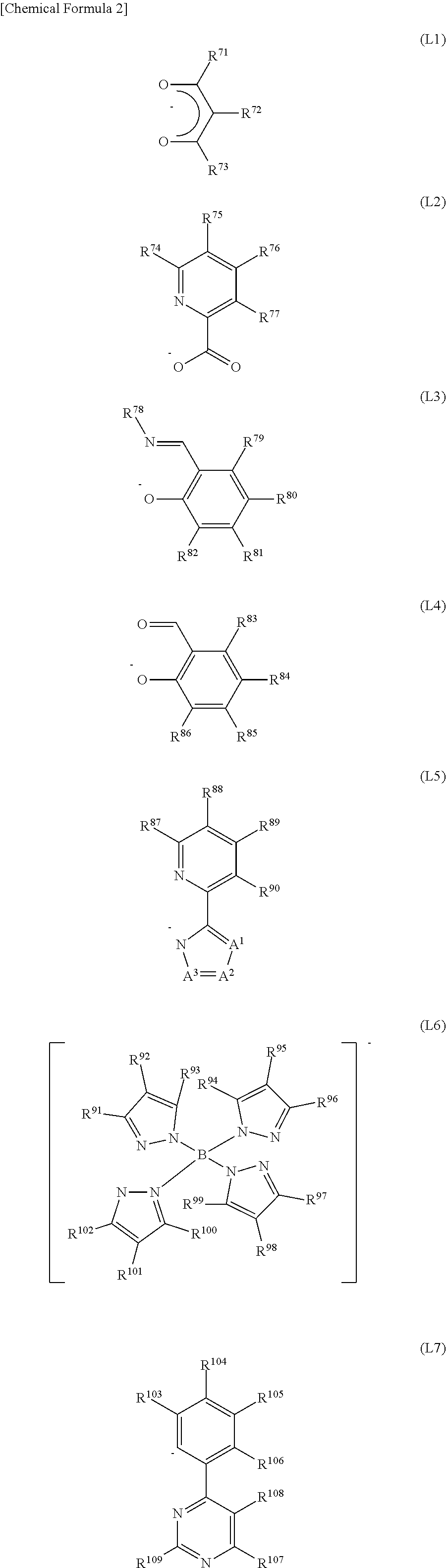

Note that in the formulae, each of R⁷¹ to R¹⁰⁹ independently represents hydrogen, a substituted or unsubstituted alkyl group having 1 to 6 carbon atoms, a halogen group, a vinyl group, a substituted or unsubstituted haloalkyl group having 1 to 6 carbon atoms, a substituted or unsubstituted alkoxy group having 1 to 6 carbon atoms, or a substituted or unsubstituted alkylthio group having 1 to 6 carbon atoms. Each of A¹ to A³ independently represents nitrogen, sp² hybridized carbon bonded to hydrogen, or sp² hybridized carbon with a substituent. The substituent is an alkyl group having 1 to 6 carbon atoms, a halogen group, a haloalkyl group having 1 to 6 carbon atoms, or a phenyl group.

Another embodiment of the present invention is an organometallic iridium complex including a structure represented by General Formula (G4) below. In LC analysis of the organometallic iridium complex, an organometallic iridium complex which has a monochlorinated ligand among the plurality of ligands is detected as an impurity of 0.1% or less by quantitating using peak area count with a PDA detector.

Another embodiment of the present invention is an organometallic iridium complex including the structure represented by General Formula (G4) below. In LC-MS analysis of the organometallic iridium complex, an organometallic iridium complex is detected as an impurity concentration of 0.1% or less by quantitating using peak area count with a PDA detector, and the impurity is observed at m/z=Mass number of the organometallic iridium complex+35±1.

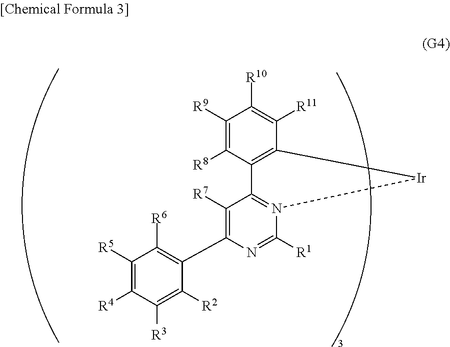

In General Formula (G4), each of R¹ to R¹¹ independently represents hydrogen or a substituted or unsubstituted alkyl group having 1 to 6 carbon atoms.

Another embodiment of the present invention is an organometallic iridium complex represented by Structural Formula (100) below. In LC analysis of the organometallic iridium complex, an organometallic iridium complex which has a monochlorinated ligand among the plurality of ligands is detected as an impurity concentration of 0.1% or less by quantitating using peak area count with a PDA detector.

Another embodiment of the present invention is an organometallic iridium complex represented by Structural Formula (100) below. In LC-MS analysis of the organometallic iridium complex, an organometallic iridium complex is detected as an impurity concentration of 0.1% or less by quantitating using peak area count with a

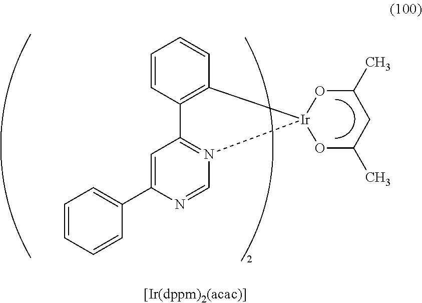

PDA detector, and the impurity is observed at m/z=Mass number of the organometallic iridium complex+35±1.

### [Chemical Formula 4]

Another embodiment of the present invention is a synthesis method of the high-purity organometallic iridium complexes including any of the above structures. In the synthesis method of the high-purity organometallic iridium complex that is one embodiment of the present invention, the complex is synthesized using iridium chloride hydrate and a ligand, and the iridium content of the iridium chloride hydrate is preferably greater than or equal to 51.00% and less than 54.00%; the high-purity organometallic iridium complex preferably includes two or more ligands each of which includes a heteroaromatic ring having a coordinatable nitrogen atom. In a synthesis method of the high-purity organometallic iridium complex that is one embodiment of the present invention, a ligand that includes a heteroaromatic ring having a coordinatable nitrogen atom and iridium chloride hydrate in which the atomic ratio of chlorine to iridium is greater than or equal to 2.5 and less than 3.1, preferably 1 to greater than or equal to 2.5 and less than 3.0 are used. In ultra high performance liquid chromatography (UHPLC) of the ligand, it is preferable that an impurity observed as an ion which includes an isotope of chlorine be less than 0.1% when measured by quantitating using peak area count with a PDA detector, that is, the purity of the high-purity organometallic iridium complex be 99.9% or more. In this specification, UHPLC was performed with ACQUITY Ultra Performance LC (UPLC, registered trademark).

The organometallic iridium complex of one embodiment of the present invention can emit phosphorescence. That is, the organometallic iridium complex of one embodiment of the present invention is very effective for the following reason: it can provide luminescence from a triplet excited state and can exhibit emission, and therefore higher efficiency is possible when the organometallic iridium complex is applied to a light-emitting element. Thus, one embodiment of the present invention also includes a light-emitting element in which the organometallic iridium complex of one embodiment of the present invention is used.

The present invention includes, in its scope, not only a light-emitting device including the light-emitting element but also a lighting device including the light-emitting device. The light-emitting device in this specification refers to an image display device and a light source (e.g., a lighting device). In addition, the light-emitting device might include any of the following modules in its category: a module in which a connector such as a flexible printed circuit (FPC) or a tape carrier package (TCP) is connected to a light-emitting device; a module in which a printed wiring board is provided on the tip of a TCP; and a module in which an integrated circuit (IC) is directly mounted on a light-emitting element by a chip on glass (COG) method.

One embodiment of the present invention can provide a high-purity organometallic iridium complex. One embodiment of the present invention can provide a synthesis method of a high-purity organometallic iridium complex. One embodiment of the present invention can provide a light-emitting element including the high-purity organometallic iridium complex and having low drive voltage. One embodiment of the present invention can provide a light-emitting device, an electronic device, or a lighting device that has low power consumption and has a long lifetime.

### BRIEF DESCRIPTION OF THE DRAWINGS

FIGS. 1A and 1B illustrate structures of light-emitting elements.

FIGS. 2A and 2B illustrate structures of light-emitting elements.

FIGS. 3A to 3C illustrate light-emitting devices.

FIGS. 4A to 4F illustrate electronic devices.

FIGS. 5A to 5C illustrate an electronic device.

FIGS. 6A to 6D illustrate lighting devices.

FIG. 7 illustrates lighting devices.

FIGS. 8A and 8B illustrate an example of a touch panel.

FIGS. 9A and 9B illustrate an example of a touch panel.

FIGS. 10A and 10B illustrate an example of a touch panel.

FIGS. 11A and 11B are a block diagram and a timing chart of a touch sensor.

FIG. 12 is a circuit diagram of a touch sensor.

FIG. 13 illustrates a light-emitting element.

FIG. 14 shows current density-luminance characteristics of Light-emitting Element 1, Comparative Light-emitting Element 2, and Comparative Light-emitting Element 3.

FIG. 15 shows voltage-luminance characteristics of Light-emitting Element 1, Comparative Light-emitting Element 2, and Comparative Light-emitting Element 3.

FIG. 16 shows luminance-current efficiency characteristics of Light-emitting Element 1, Comparative Light-emitting Element 2, and Comparative Light-emitting Element 3.

FIG. 17 shows voltage-current characteristics of Light-emitting Element 1, Comparative Light-emitting Element 2, and Comparative Light-emitting Element 3.

FIG. 18 shows emission spectra of Light-emitting Element 1, Comparative Light-emitting Element 2, and Comparative Light-emitting Element 3.

FIG. 19 shows reliability of Light-emitting Element 1, Comparative Light-emitting Element 2, and Comparative Light-emitting Element 3.

### DETAILED DESCRIPTION OF THE INVENTION

Hereinafter, embodiments of the present invention will be described with reference to the accompanying drawings. Note that the present invention is not limited to the following description, and modes and details thereof can be variously modified without departing from the spirit and scope of the present invention. Therefore, the present invention should not be construed as being limited to the description in the following embodiments.

Note that the terms “film” and “layer” can be interchanged with each other according to circumstances. For example, in some cases, the term “conductive film” can be used instead of the term “conductive layer,” and the term “insulating layer” can be used instead of the term “insulating film.

### Embodiment 1

In this embodiment, an organometallic iridium complex of one embodiment of the present invention is described.

The organometallic iridium complex of one embodiment of the present invention includes, as shown in General Formula (G0) below, iridium and a plurality of ligands cyclometallated to the iridium.

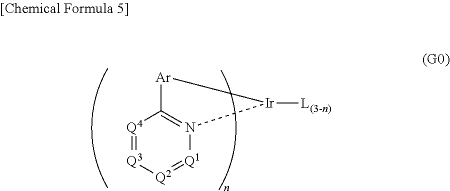

In General Formula (G0), n is 2 or 3. L represents a monoanionic ligand. Ar represents a substituted or unsubstituted arylene group having 6 to 10 carbon atoms. At least one of Q¹ to Q⁴ represents nitrogen and the others each represent substituted or unsubstituted carbon. Note that each of a substituent of any of Q¹ to Q⁴ representing carbon and a substituent of Ar is independently hydrogen, a substituted or unsubstituted alkyl group having 1 to 6 carbon atoms, or a substituted or unsubstituted phenyl group. When two or more of Q¹ to Q⁴ each represent carbon having a substituent, adjacent substituents may be bonded to each other to form a ring.

Here, specific examples of Ar in General Formula (G0) include a phenylene group, a phenylene group substituted with one or more alkyl groups each having 1 to 6 carbon atoms, a phenylene group substituted with one or more alkoxy groups each having 1 to 6 carbon atoms, a phenylene group substituted with one or more alkylthio groups each having 1 to 6 carbon atoms, a phenylene group substituted with one or more aryl groups each having 6 to 10 carbon atoms, a phenylene group substituted with one or more halogen groups, a phenylene group substituted with one or more haloalkyl groups each having 1 to 6 carbon atoms, a substituted or unsubstituted biphenyl-diyl group, and a substituted or unsubstituted naphthalene-diyl group.

In the case where a substituent of any of Q¹ to Q⁴ representing carbon and a substituent of Ar are each an alkyl group having 1 to 6 carbon atoms in General Formula (G0), specific examples of the alkyl group having 1 to 6 carbon atoms include a methyl group, an ethyl group, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, a sec-hexyl group, a tert-hexyl group, a neohexyl group, a 3-methylpentyl group, a 2-methylpentyl group, a 2-ethylbutyl group, a 1,2-dimethylbutyl group, and a 2,3-dimethylbutyl group. In the case where a substituent of any of Q¹ to Q⁴ representing carbon and a substituent of Ar are each an aryl group having 6 to 10 carbon atoms in General Formula (G0), specific examples of the aryl group having 6 to 10 carbon atoms include a phenyl group, a phenyl group substituted with one or more alkyl groups each having 1 to 6 carbon atoms, a phenyl group substituted with one or more alkoxy groups each having 1 to 6 carbon atoms, a phenyl group substituted with one or more alkylthio groups each having 1 to 6 carbon atoms, a phenyl group substituted with an amino group having 1 to 6 carbon atoms, a phenyl group substituted with one or more aryl groups each having 6 to 10 carbon atoms, a phenyl group substituted with one or more halogen groups, a phenyl group substituted with one or more haloalkyl groups each having 1 to 6 carbon atoms, and a naphthalen-yl group.

In General Formula (G0), specific examples of the heteroaromatic ring formed by Q¹ to Q⁴ at least one of which represents nitrogen include pyridazine where only Q¹ represents nitrogen, pyrimidine where either Q² or Q⁴ represents nitrogen, pyrazine where only Q³ represents nitrogen, and triazine where each of Q² and Q⁴ represents nitrogen. When two or more of Q¹ to Q⁴ each represent carbon having a substituent and adjacent substituents are bonded to each other to form a ring, specific examples of the heteroaromatic ring include cinnoline, phthalazine, quinazoline, quinoxaline, and pteridine.

Note that the organometallic iridium complex represented by General Formula (G0) includes a plurality of ligands and two or more of the ligands each include a heteroaromatic ring having a coordinatable nitrogen atom, as described above. In synthesis of the organometallic iridium complex with a ligand having such a structure, reaction between the ligand and iridium chloride hydrate might cause an interaction between a nitrogen atom that is contained in the ligand and does not coordinate to iridium and the iridium contained in a raw material, and the iridium might act as a catalyst. Accordingly, monohalogenation of the ligand due to a chlorine atom of the iridium chloride hydrate might proceed easily. In that case, an impurity of the organometallic iridium complex is easily generated by monochlorination of one of the plurality of ligands.

Note that such an organometallic iridium complex whose ligand contains an impurity such as a halogen is very likely to be inferior to a high-purity organometallic iridium complex that contains such an impurity as little as possible in terms of the characteristics of a light-emitting element. For example, when a light-emitting element that includes a light-emitting layer containing an organometallic iridium complex is fabricated, an impurity contained in the organometallic complex adversely affects the characteristics and reliability of the element. Thus, in synthesis of the organometallic iridium complex, it is necessary to inhibit generation of an impurity due to monochlorination of one of the plurality of ligands at the stage of forming a dinuclear complex using a halogenated iridium compound and the ligand that includes the heteroaromatic ring having a coordinatable nitrogen atom.

In view of the above, a synthesis method of the organometallic iridium complex represented by General Formula (G0) in which a halogen in a ligand is reduced is described in this embodiment.

For example, the organometallic iridium complex represented by General Formula (G0) can be synthesized under Synthesis Schemes (A-1) and (A-2) below. As shown in Synthesis Scheme (A-1) below, iridium chloride hydrate and a ligand represented by General Formula (L0) are heated in an inert gas atmosphere in the absence of a solvent or in an alcohol-based solvent (e.g., glycerol, ethylene glycol, 2-methoxyethanol, and 2-ethoxyethanol) alone, or a mixed solvent of water and one or more kinds of such alcohol-based solvents, whereby a dinuclear complex (P) that is a chlorine-bridged organometallic complex can be obtained. There is no particular limitation on a heating means, and an oil bath, a sand bath, or an aluminum block may be used. Alternatively, microwaves can be used for heating.

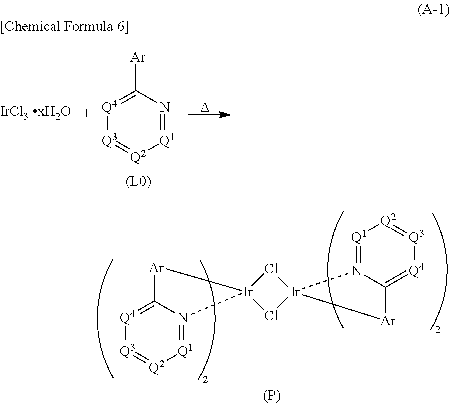

In Synthesis Scheme (A-1) above, n is 2 or 3. L represents a monoanionic ligand. Ar represents a substituted or unsubstituted arylene group having 6 to 10 carbon atoms. At least one of Q¹ to Q⁴ represents nitrogen and the others each represent substituted or unsubstituted carbon. Note that each of a substituent of any of Q¹ to Q⁴ representing carbon and a substituent of Ar is independently hydrogen, a substituted or unsubstituted alkyl group having 1 to 6 carbon atoms, or a substituted or unsubstituted phenyl group. When two or more of Q¹ to Q⁴ each represent carbon having a substituent, adjacent substituents may be bonded to each other to form a ring.

Furthermore, as shown in Synthesis Scheme (A-2), the Binuclear complex (P) obtained under Synthesis Scheme (A-1) above is reacted with HL which is a raw material of a monoanionic ligand or the ligand represented by General Formula (L0) in an inert gas atmosphere, whereby a proton of HL or the ligand represented by General Formula (L0) is separated and L or the ligand represented by General Formula (L0) coordinates to the central metal, iridium. Thus, the organometallic complex of one embodiment of the present invention represented by General Formula (G0) can be obtained. Alternatively, the organometallic complex of one embodiment of the present invention represented by General Formula (G0) may be obtained by the following method: the Binuclear complex (P) is reacted with silver salt or the like that is an antichlor, and is then reacted with HL which is a raw material of a monoanionic ligand or the ligand represented by General Formula (L0) in an inert gas atmosphere. There is no particular limitation on a heating means, and an oil bath, a sand bath, or an aluminum block may be used. Alternatively, microwaves can be used for heating.

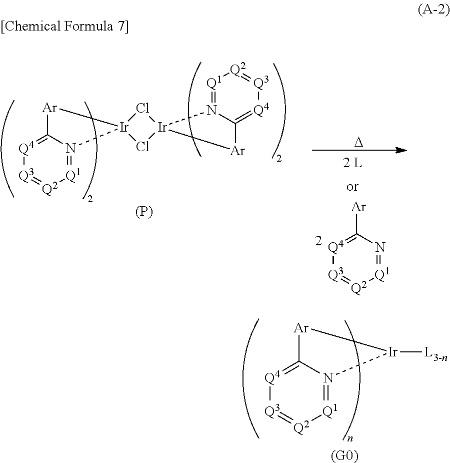

In Synthesis Scheme (A-2) above, n is 2 or 3. L represents a monoanionic ligand. Ar represents a substituted or unsubstituted arylene group having 6 to 10 carbon atoms. At least one of Q¹ to Q⁴ represents nitrogen and the others each represent substituted or unsubstituted carbon. Note that each of a substituent of any of Q¹ to Q⁴ representing carbon and a substituent of Ar is independently hydrogen, a substituted or unsubstituted alkyl group having 1 to 6 carbon atoms, or a substituted or unsubstituted phenyl group. When two or more of Q¹ to Q⁴ each represent carbon having a substituent, adjacent substituents may be bonded to each other to form a ring.

Under Synthesis Scheme (A-1), the complex is formed using iridium chloride hydrate and the ligand represented by General Formula (L0). By the use of the ligand (L0), an impurity that is detected as an ion including an isotope of chlorine is less than 0.1% by quantitating using peak area count in UPLC and either the iridium chloride hydrate whose iridium content is greater than or equal to 51.00% and less than 54.00% or the iridium chloride hydrate in which the ratio of iridium to chlorine is 1 to greater than or equal to 2.5 and less than 3.1, preferably 1 to greater than or equal to 2.5 and less than 3.0, the monohalogenation of the ligand due to a chlorine atom of the iridium chloride hydrate that might be caused at the time of reaction between the ligand (L0) and the iridium chloride hydrate is inhibited in the following manner: a nitrogen atom that is contained in the ligand (L0) and does not coordinate to iridium and the iridium contained in a raw material interact with each other, and the iridium acts as a catalyst. In a resulting dinuclear complex, generation of an impurity of the organometallic iridium complex by monochlorination of one of the plurality of ligands is inhibited, and this dinuclear complex is also one embodiment of the present invention. In the organometallic complex of one embodiment of the present invention that is synthesized under Synthesis Scheme (A-2) using the above dinuclear complex, an impurity of the organometallic iridium complex is unlikely to be generated by monochlorination of one of the plurality of ligands. This leads to a long lifetime of a light-emitting element.

The organometallic iridium complex (General Formula (G0)) of one embodiment of the present invention obtained by the above synthesis method includes iridium and a plurality of ligands cyclometallated to the iridium. Each of the plurality of ligands includes a heteroaromatic ring having a coordinatable nitrogen atom. In LC analysis of the organometallic iridium complex, an impurity which is monochlorinated in one of the plurality of ligands is 0.1% or less by quantitating using peak area count with a PDA detector.

The organometallic iridium complex (General Formula (G0)) of one embodiment of the present invention obtained by the above synthesis method includes iridium and a plurality of ligands cyclometallated to the iridium. Each of the plurality of ligands includes a heteroaromatic ring having a coordinatable nitrogen atom. In LC-MS analysis of the organometallic iridium complex, an impurity detected at a mass-to-charge ratio represented by the following expression, the mass number of the organometallic iridium complex+35±1, is 0.1% or less by an area normalization method using a PDA detector.

Next, specific structural formulae of the above-described organometallic iridium complexes, each of which is one embodiment of the present invention, are shown (Structural Formulae (100) to (121) below). Note that the present invention is not limited thereto.

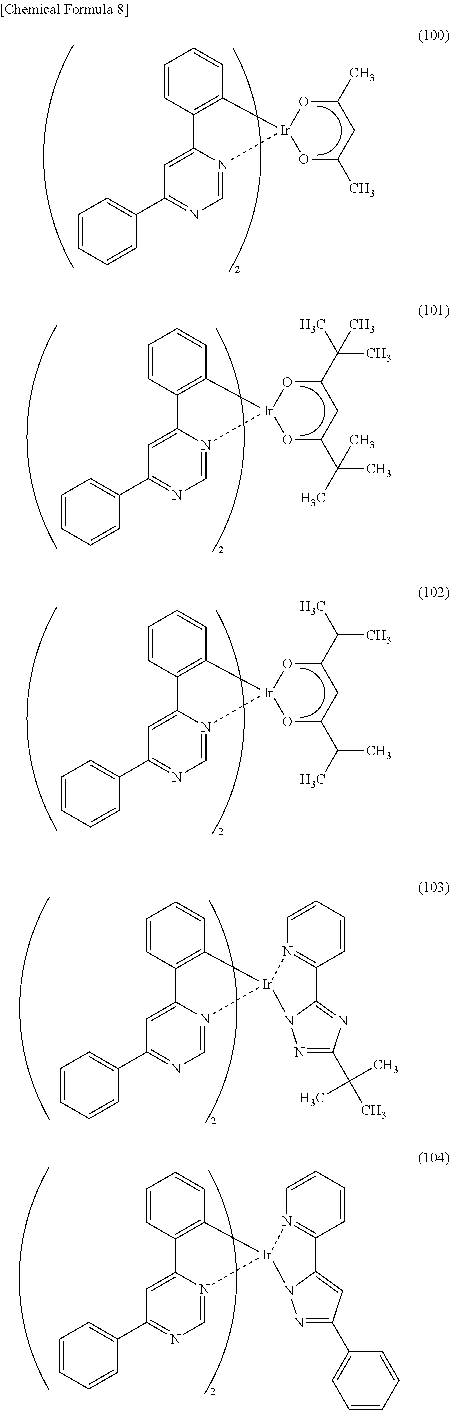

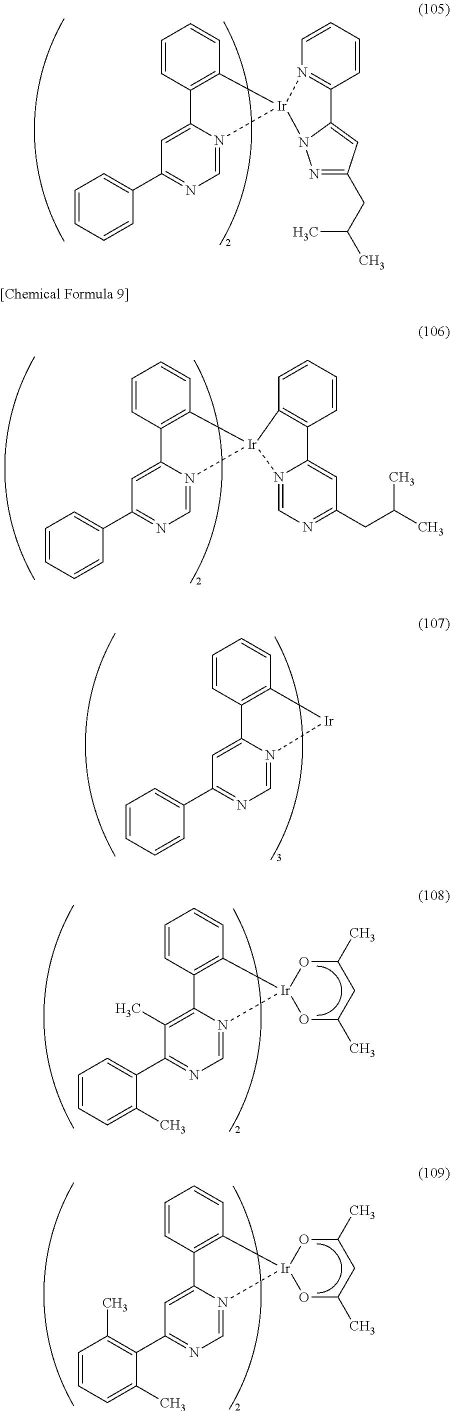

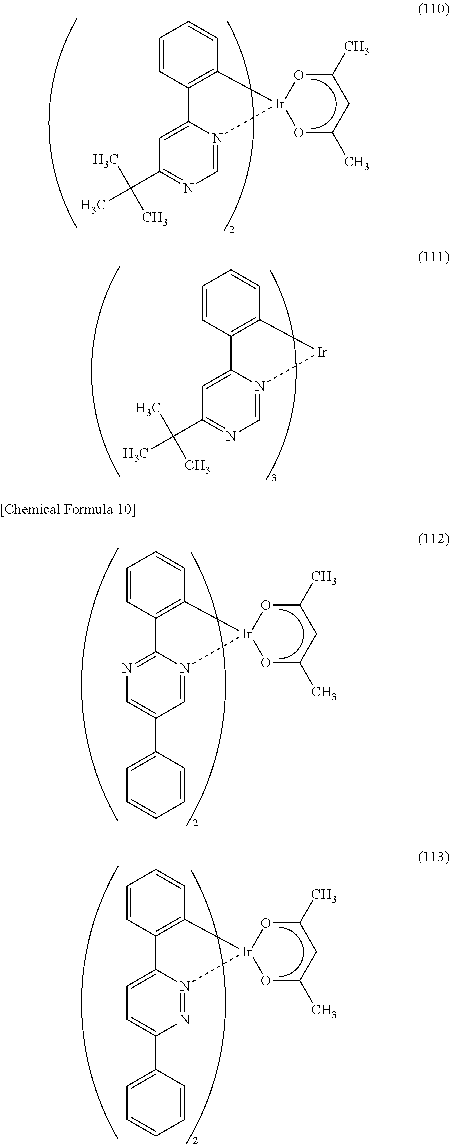

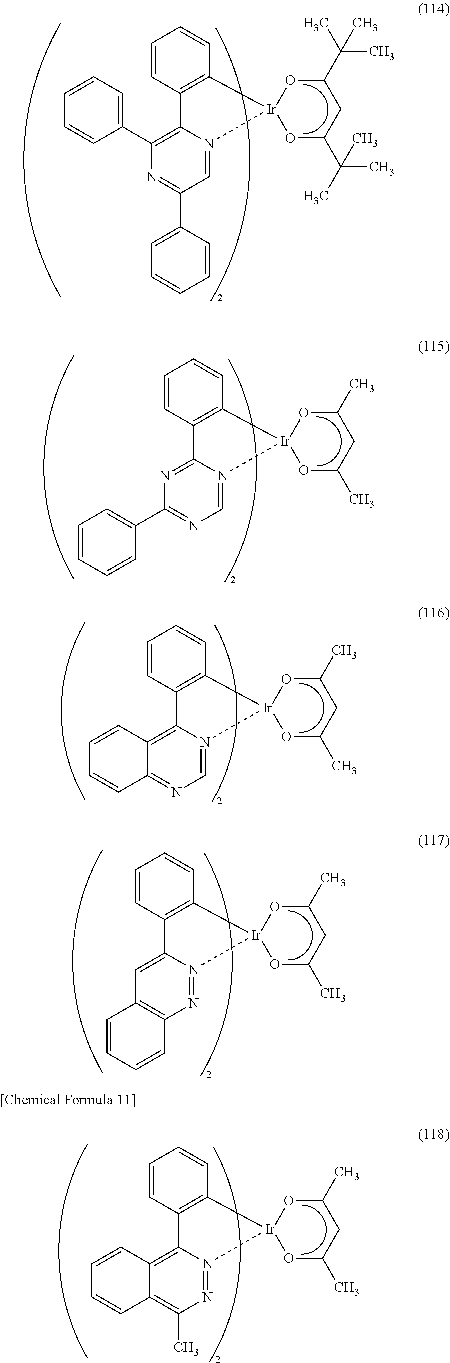

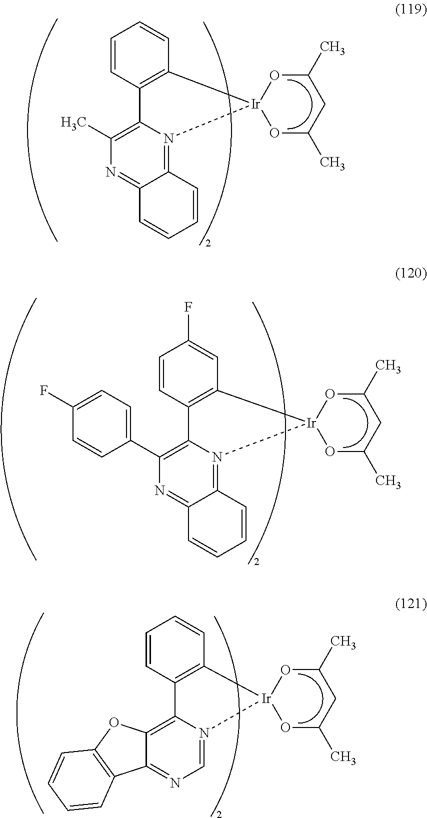

Note that the organometallic iridium complexes represented by Structural Formulae (100) to (121) above are substances capable of emitting phosphorescence. Note that there can be geometrical isomers and stereoisomers of these substances, as characterized by the type of the ligand. Each of the isomers is also an organometallic iridium complex of one embodiment of the present invention.

The above is the description of the example of a method for synthesizing an organometallic iridium complex of one embodiment of the present invention; however, the present invention is not limited thereto and a different synthesis method may be employed.

Furthermore, an organometallic iridium complex whose ligand has a structure different from the above-described structure is also an organometallic iridium complex of one embodiment of the present invention. Examples include an organometallic iridium complex represented by General Formula (G0′) below.

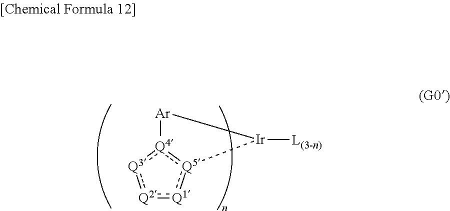

In General Formula (G0′), n is 2 or 3. L represents a monoanionic ligand. Ar represents a substituted or unsubstituted arylene group having 6 to 10 carbon atoms. The ring formed by Q^{1′} to Q^{5′} is a five-membered heterocyclic compound. Each of Q^{1′} to Q^{5′} independently represents nitrogen or substituted or unsubstituted carbon. Note that each of a substituent of any of Q^{1′} to Q^{3′} representing carbon and a substituent of Ar is independently hydrogen, a substituted or unsubstituted alkyl group having 1 to 6 carbon atoms, or a substituted or unsubstituted phenyl group. When two or more of Q^{1′} to Q^{3′} each represent carbon having a substituent, adjacent substituents may be bonded to each other to form a ring.

Here, specific examples of Ar in General Formula (G0′) include a phenylene group, a phenylene group substituted with one or more alkyl groups each having 1 to 6 carbon atoms, a phenylene group substituted with one or more alkoxy groups each having 1 to 6 carbon atoms, a phenylene group substituted with one or more alkylthio groups each having 1 to 6 carbon atoms, a phenylene group substituted with one or more aryl groups each having 6 to 10 carbon atoms, a phenylene group substituted with one or more halogen groups, a phenylene group substituted with one or more haloalkyl groups each having 1 to 6 carbon atoms, a substituted or unsubstituted biphenyl-diyl group, and a substituted or unsubstituted naphthalene-diyl group.

In the case where a substituent of any of Q^{1′} to Q^{3′} representing carbon and a substituent of Ar are each an alkyl group having 1 to 6 carbon atoms in General Formula (G0′), specific examples of the alkyl group having 1 to 6 carbon atoms include a methyl group, an ethyl group, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, a sec-hexyl group, a tert-hexyl group, a neohexyl group, a 3-methylpentyl group, a 2-methylpentyl group, a 2-ethylbutyl group, a 1,2-dimethylbutyl group, and a 2,3-dimethylbutyl group. In the case where a substituent of any of Q^{1′} to Q^{3′} representing carbon and a substituent of Ar are each an aryl group having 6 to 10 carbon atoms in General Formula (G0′), specific examples of the aryl group having 6 to 10 carbon atoms include a phenyl group, a phenyl group substituted with one or more alkyl groups each having 1 to 6 carbon atoms, a phenyl group substituted with one or more alkoxy groups each having 1 to 6 carbon atoms, a phenyl group substituted with one or more alkylthio groups each having 1 to 6 carbon atoms, a phenyl group substituted with an amino group having 1 to 6 carbon atoms, a phenyl group substituted with one or more aryl groups each having 6 to 10 carbon atoms, a phenyl group substituted with one or more halogen groups, a phenyl group substituted with one or more haloalkyl groups each having 1 to 6 carbon atoms, and a naphthalen-yl group.

In General Formula (G0′), specific examples of the ring formed by Q^{1′} to Q^{5′} each of which independently represents carbon or nitrogen include pyrazole where Q^{4′} and Q^{5′} each represent nitrogen, imidazole where Q^{3′} and Q^{5′} each represent nitrogen, triazole where Q^{5′} and two of Q^{1′} to Q^{4′} each represent nitrogen, and imidazole carbene where Q^{1′} and Q^{4′} each represent nitrogen. When two or more of Q^{1′} to Q^{3′} each represent carbon having a substituent and adjacent substituents are bonded to each other to form a ring, specific examples of the ring include benzimidazole and benzimidazole carbene.

Next, specific structural formulae of the organometallic iridium complex represented by General Formula (G0′) above, which is an organometallic iridium complex of one embodiment of the present invention, are shown (Structural Formulae (200) to (206) below). Note that the present invention is not limited thereto.

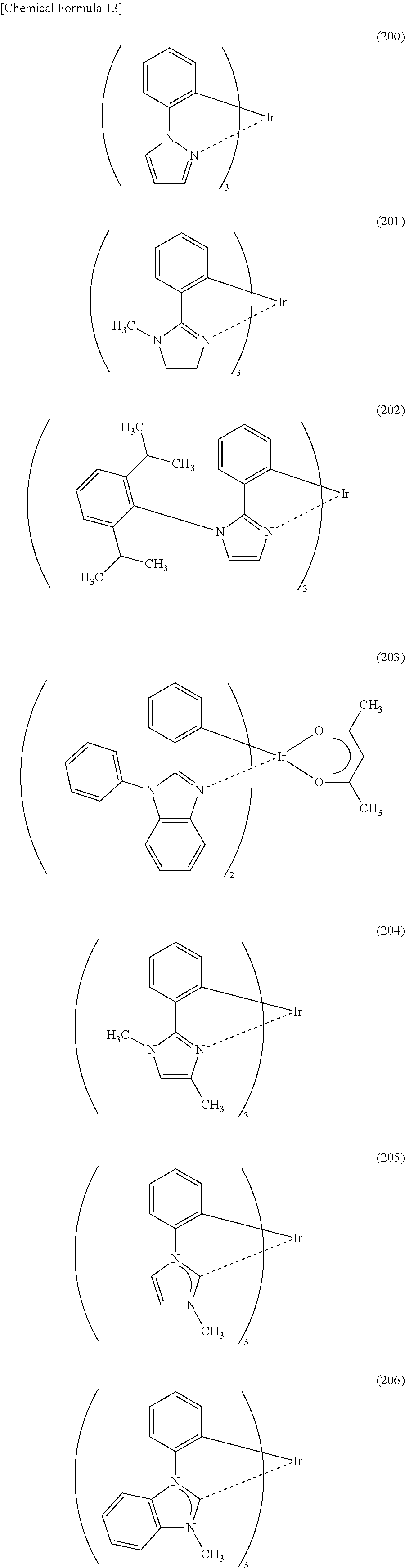

Note that the organometallic iridium complexes represented by Structural Formulae (200) to (206) above are also substances capable of emitting phosphorescence. Note that there can be geometrical isomers and stereoisomers of these substances, as characterized by the type of the ligand. Each of the isomers is also an organometallic iridium complex of one embodiment of the present invention.

The above-described organometallic iridium complex of one embodiment of the present invention can emit phosphorescence and thus can be used as a light-emitting material or a light-emitting substance of a light-emitting element.

With the use of the organometallic iridium complex of one embodiment of the present invention, a light-emitting element, a light-emitting device, an electronic device, or a lighting device with high emission efficiency can be obtained. Alternatively, it is possible to obtain a light-emitting element, a light-emitting device, an electronic device, or a lighting device with low power consumption.

In Embodiment 1, one embodiment of the present invention has been described. Other embodiments of the present invention are described in Embodiments 2 to 8. Note that one embodiment of the present invention is not limited thereto. In other words, various embodiments of the invention are described in this embodiment and the other embodiments, and one embodiment of the present invention is not limited to a particular embodiment. The example in which one embodiment of the present invention is applied to a light-emitting element is described; however, one embodiment of the present invention is not limited thereto. Depending on circumstances or conditions, one embodiment of the present invention may be applied to objects other than a light-emitting element. Furthermore, depending on circumstances or conditions, one embodiment of the present invention is not necessarily applied to a light-emitting element. The example in which iridium is used has been described above as one embodiment of the present invention; however, one embodiment of the present invention is not limited thereto. Depending on circumstances or conditions, a metal other than iridium may be used in one embodiment of the present invention. Alternatively, depending on circumstances or conditions, iridium is not necessarily used in one embodiment of the present invention.

The structure described in this embodiment can be combined as appropriate with any of the structures described in other embodiments.

### Embodiment 2

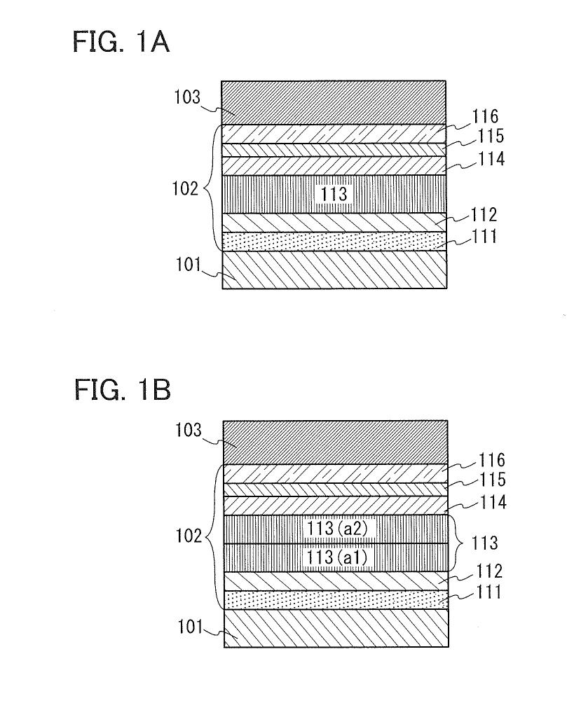

In this embodiment, a light-emitting element in which the organometallic iridium complex described in Embodiment 1 as one embodiment of the present invention is used for a light-emitting layer is described with reference to FIGS. 1A and 1B.

In the light-emitting element described in this embodiment, an EL layer 102 including a light-emitting layer 113 is interposed between a pair of electrodes (a first electrode (anode) 101 and a second electrode (cathode) 103), and the EL layer 102 includes a hole-injection layer 111, a hole-transport layer 112, an electron-transport layer 114, an electron-injection layer 115, a charge-generation layer 116, and the like in addition to the light-emitting layer 113.

When a voltage is applied to the light-emitting element, holes injected from the first electrode side and electrons injected from the second electrode side recombine in the light-emitting layer; with energy generated by the recombination, a light-emitting substance such as the organometallic iridium complex that is contained in the light-emitting layer emits light.

The hole-injection layer 111 included in the EL layer 102 contains a substance having a high hole-transport property and an acceptor substance. When electrons are extracted from the substance having a high hole-transport property with the acceptor substance, holes are generated. Thus, holes are injected from the hole-injection layer 111 into the light-emitting layer 113 through the hole-transport layer 112.

The charge-generation layer 116 is a layer containing a substance having a high hole-transport property and an acceptor substance. Electrons are extracted from the substance having a high hole-transport property with the acceptor substance, and the extracted electrons are injected from the electron-injection layer 115 having an electron-injection property into the light-emitting layer 113 through the electron-transport layer 114.

A specific example in which the light-emitting element described in this embodiment is fabricated is described below.

For the first electrode (anode) 101 and the second electrode (cathode) 103, a metal, an alloy, an electrically conductive compound, a mixture thereof, and the like can be used. Specific examples are indium oxide-tin oxide (indium tin oxide), indium oxide-tin oxide containing silicon or silicon oxide, indium oxide-zinc oxide (indium zinc oxide), indium oxide containing tungsten oxide and zinc oxide, gold (Au), platinum (Pt), nickel (Ni), tungsten (W), chromium (Cr), molybdenum (Mo), iron (Fe), cobalt (Co), copper (Cu), palladium (Pd), and titanium (Ti). In addition, an element belonging to Group 1 or Group 2 of the periodic table, for example, an alkali metal such as lithium (Li) or cesium (Cs), an alkaline earth metal such as calcium (Ca) or strontium (Sr), magnesium (Mg), an alloy containing such an element (MgAg or AlLi), a rare earth metal such as europium (Eu) and ytterbium (Yb), an alloy containing such an element, graphene, and other materials can be used. The first electrode (anode) 101 and the second electrode (cathode) 103 can be formed by, for example, a sputtering method or an evaporation method (including a vacuum evaporation method).

Specific examples of the substance having a high hole-transport property, which is used for the hole-injection layer 111, the hole-transport layer 112, and the charge-generation layer 116, include aromatic amine compounds such as 4,4′-bis[N-(1-naphthyl)-N-phenylamino]biphenyl (abbreviation: NPB or α-NPD), N,N′-bis(3-methylphenyl)-N,N′-diphenyl-[1,1′-biphenyl]-4,4′-diamine (abbreviation: TPD), 4,4′,4″-tris(carbazol-9-yl)triphenylamine (abbreviation: TCTA), 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), and 4,4′-bis[N-(spiro-9,9′-bifluoren-2-yl)-N-phenylamino]biphenyl (abbreviation: BSPB); 3-[N-(9-phenylcarbazol-3-yl)-N-phenylamino]-9-phenylcarbazole (abbreviation: PCzPCA1); 3,6-bis[N-(9-phenylcarbazol-3-yl)-N-phenylamino]-9-phenylcarbazole (abbreviation: PCzPCA2); and 3-[N-(1-naphthyl)-N-(9-phenylcarbazol-3-yl)amino]-9-phenylcarbazole (abbreviation: PCzPCN1). Other examples include carbazole derivatives such as 4,4′-di(N-carbazolyl)biphenyl (abbreviation: CBP), 1,3,5-tris[4-(N-carbazolyl)phenyl]benzene (abbreviation: TCPB), and 9-[4-(10-phenyl-9-anthracenyl)phenyl]-9H-carbazole (abbreviation: CzPA). The substances listed here are mainly ones that have a hole mobility of 1×10⁻⁶ cm²/Vs or higher. Note that any substance other than the substances listed here may be used as long as the hole-transport property is higher than the electron-transport property.

A high molecular compound such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}-phenyl)methacrylamide] (abbreviation: PTPDMA), or poly[N,N′-bis(4-butylphenyl)-N,N′-bis(phenyl)benzidine] (abbreviation: Poly-TPD) can also be used.

Examples of the acceptor substance that is used for the hole-injection layer 111 and the charge-generation layer 116 include oxides of metals belonging to Groups 4 to 8 of the periodic table. Specifically, molybdenum oxide is particularly preferable.

The light-emitting layer 113 contains a light-emitting substance. Note that the organometallic iridium complex described in Embodiment 1 can be used as the light-emitting substance, and the light-emitting layer 113 may contain, as a host material, a substance having higher triplet excitation energy than the organometallic iridium complex (guest material). In addition to the light-emitting substance, two kinds of organic compounds that can form an exciplex (also called an excited complex) at the time of recombination of carriers (electrons and holes) in the light-emitting layer may be contained.

Examples of the organic compounds that can be used as the above two kinds of organic compounds include compounds having an arylamine skeleton, such as 2,3-bis(4-diphenylaminophenyl)quinoxaline (abbreviation: TPAQn) and NPB, carbazole derivatives such as CBP and 4,4′,4″-tris(carbazol-9-yl)triphenylamine (abbreviation: TCTA), and metal complexes such as bis[2-(2-hydroxyphenyl)pyridinato]zinc (abbreviation: Znpp₂), bis[2-(2-hydroxyphenyl)benzoxazolato]zinc (abbreviation: Zn(BOX)₂), bis(2-methyl-8-quinolinolato)(4-phenylphenolato)aluminum (abbreviation: BAlq), and tris(8-quinolinolato)aluminum (abbreviation: Alq₃). Alternatively, a high molecular compound such as PVK can be used.

Note that in the case where the light-emitting layer 113 contains the above-described organometallic iridium complex (guest material) and the host material, phosphorescence with high emission efficiency can be obtained from the light-emitting layer 113.

In the light-emitting element, the light-emitting layer 113 does not necessarily have the single-layer structure shown in FIG. 1A and may have a stacked-layer structure including two or more layers as shown in FIG. 1B. In that case, each layer in the stacked-layer structure emits light. For example, fluorescence is obtained from a first light-emitting layer 113(a1), and phosphorescence is obtained from a second light-emitting layer 113(a2) stacked over the first light-emitting layer. Note that the stacking order may be reversed. It is preferable that light emission due to energy transfer from an exciplex to a dopant be obtained from the layer that emits phosphorescence. In the case where blue light emission is obtained from one of the first and second light-emitting layers, orange or yellow light emission can be obtained from the other layer. Each layer may contain various kinds of dopants.

Note that in the case where the light-emitting layer 113 has a stacked-layer structure, one or more of the organometallic iridium complex described in Embodiment 1, a light-emitting substance converting singlet excitation energy into light emission, and a light-emitting substance converting triplet excitation energy into light emission can be used alone or in combination, for example. In that case, the following substances can be used.

As an example of the light-emitting substance converting singlet excitation energy into light emission, a substance which emits fluorescence (a fluorescent compound) can be given.

Examples of the substance emitting fluorescence include N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra(tert-butyl)perylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis[N,N′,N′-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N,N-triphenyl-1,4-phenylenediamine (abbreviation: 2DPAPPA), N,N,N,′,N′,N″,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N,N-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo [ij] quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij] quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), and 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM).

Examples of the light-emitting substance converting triplet excitation energy into light emission include a substance which emits phosphorescence (a phosphorescent compound) and a thermally activated delayed fluorescent (TADF) material which emits thermally activated delayed fluorescence. Note that “delayed fluorescence” exhibited by the TADF material refers to light emission having the same spectrum as normal fluorescence and an extremely long lifetime. The lifetime is 1×10⁻⁶ seconds or longer, preferably 1×10⁻³ seconds or longer.

Examples of the substance emitting phosphorescence include bis{2-[3′,5′-bis(trifluoromethyl)phenyl]pyridinato-N,C^{2′}}iridium(III) picolinate (abbreviation: [Ir(CF₃ppy)₂(pic)], bis[2-(4′,6′-difluorophenyl)pyridinato-N,C^{2′]}iridium(III) acetylacetonate (abbreviation: FIracac), tris(2-phenylpyridinato)iridium(III) (abbreviation: [Ir(ppy)₃]), bis(2-phenylpyridinato)iridium(III) acetylacetonate (abbreviation: [Ir(ppy)₂(acac)]), tris(acetylacetonato)(monophenanthroline)terbium(III) (abbreviation: [Tb(acac)₃(Phen)]), bis(benzo[h] quinolinato)iridium(III) acetylacetonate (abbreviation: [Ir(bzq)₂(acac)]), bis(2,4-diphenyl-1,3-oxazolato-N,C^{2′})iridium(III) acetylacetonate (abbreviation: [Ir(dpo)₂(acac)]), bis{2-[4′-(perfluorophenyl)phenyl]pyridinato-N,C²′}iridium(III) acetylacetonate (abbreviation: [Ir(p-PF-ph)₂(acac)]), bis(2-phenylbenzothiazolato-N,C^{2′})iridium(III) acetylacetonate (abbreviation: [Ir(bt)₂(acac)]), bis[2-(2′-benzo[4,5-a]thienyl)pyridinato-N,C^{3′}]iridium(III) acetylacetonate (abbreviation: [Ir(btp)₂(acac)]), bis(1-phenylisoquinolinato-N,C^{2′})iridium(III) acetylacetonate (abbreviation: [Ir(piq)₂(acac)]), (acetylacetonato)bis[2,3-bis(4-fluorophenyl)quinoxalinato]iridium(III) (abbreviation: [Ir(Fdpq)₂(acac)]), (acetylacetonato)bis(3,5-dimethyl-2-phenylpyrazinato)iridium(III) (abbreviation: [Ir(mppr-Me)₂(acac)]), (acetylacetonato)bis(5-isopropyl-3-methyl-2-phenylpyrazinato)iridium (III) (abbreviation: [Ir(mppr-iPr)₂(acac)]), (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)], (acetylacetonato)bis(6-tert-butyl-4-phenylpyrimidinato)iridium(III) (abbreviation: [Ir(tBuppm)₂(acac)]), bis[2-(6-phenyl-4-pyrimidinyl-κN3)phenyl-κC](2,4-pentanedionato-κ²O,O′)iridium(III) (abbreviation: [Ir(dppm)₂(acac)]), 2,3,7,8,12,13,17,18-octaethyl-21H,23H-porphyrin platinum(II) (abbreviation: PtOEP), tris(1,3-diphenyl-1,3-propanedionato)(monophenanthroline)europium(III) (abbreviation: [Eu(DBM)₃(Phen)]), and tris[1-(2-thenoyl)-3,3,3-trifluoroacetonato] (monophenanthroline)europium(III) (abbreviation: [Eu(TTA)₃(Phen)]).

Examples of the TADF material include fullerene, a derivative thereof, an acridine derivative such as proflavine, and eosin. Other examples include a metal-containing porphyrin, such as a porphyrin containing magnesium (Mg), zinc (Zn), cadmium (Cd), tin (Sn), platinum (Pt), indium (In), or palladium (Pd). Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP). Alternatively, a heterocyclic compound including a π-electron rich heteroaromatic ring and a π-electron deficient heteroaromatic ring can be used, such as 2-(biphenyl-4-yl)-4,6-bis(12-phenylindolo[2,3-a]carbazol-11-yl)-1,3,5-triazine (PIC-TRZ). Note that a material in which the π-electron rich heteroaromatic ring is directly bonded to the π-electron deficient heteroaromatic ring is particularly preferably used because both the donor property of the π-electron rich heteroaromatic ring and the acceptor property of the π-electron deficient heteroaromatic ring are increased and the energy difference between the S1 level and the T1 level becomes small.

The electron-transport layer 114 is a layer containing a substance having a high electron-transport property (also referred to as an electron-transport compound). For the electron-transport layer 114, a metal complex such as tris(8-quinolinolato)aluminum (abbreviation: Alq₃), tris(4-methyl-8-quinolinolato)aluminum (abbreviation: Almq₃), bis(10-hydroxybenzo[h]quinolinato)beryllium (abbreviation: BeBq₂), bis(2-methyl-8-quinolinolato)(4-phenylphenolato)aluminum (abbreviation: BAlq), bis[2-(2-hydroxyphenyebenzoxazolato]zinc (abbreviation: Zn(BOX)₂), or bis[2-(2-hydroxyphenyl)benzothiazolato]zinc (abbreviation: Zn(BTZ)₂) can be used. Alternatively, a heteroaromatic compound such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 3-(4′-tert-butylphenyl)-4-phenyl-5-(4″-biphenyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: Bphen), bathocuproine (abbreviation: BCP), or 4,4′-bis(5-methylbenzoxazol-2-yl)stilbene (abbreviation: BzOs) can also be used. A high molecular compound such as poly(2,5-pyridinediyl) (abbreviation: PPy), poly[(9,9-dihexylfluorene-2,7-diyl)-co-(pyridine-3,5-diyl)] (abbreviation: PF-Py), or poly[(9,9-dioctylfluorene-2,7-diyl)-co-(2,2′-bipyridine-6,6′-diyl)] (abbreviation: PF-BPy) can also be used. The substances listed here are mainly ones that have an electron mobility of 1×10⁻⁶ cm²/Vs or higher. Note that any substance other than the substances listed here may be used for the electron-transport layer 114 as long as the electron-transport property is higher than the hole-transport property.

The electron-transport layer 114 is not limited to a single layer, but may be a stack of two or more layers each containing any of the substances listed above.

The electron-injection layer 115 is a layer containing a substance having a high electron-injection property. For the electron-injection layer 115, an alkali metal, an alkaline earth metal, or a compound thereof, such as lithium fluoride (LiF), cesium fluoride (CsF), calcium fluoride (CaF₂), or lithium oxide (LiOₓ) can be used. A rare earth metal compound like erbium fluoride (ErF₃) can also be used. An electride may also be used for the electron-injection layer 115. Examples of the electride include a substance in which electrons are added at high concentration to calcium oxide-aluminum oxide. Any of the substances for forming the electron-transport layer 114, which are given above, can be used.

A composite material in which an organic compound and an electron donor (donor) are mixed may also be used for the electron-injection layer 115. Such a composite material is excellent in an electron-injection property and an electron-transport property because electrons are generated in the organic compound by the electron donor. In this case, the organic compound is preferably a material that is excellent in transporting the generated electrons. Specifically, for example, the substances for forming the electron-transport layer 114 (e.g., a metal complex or a heteroaromatic compound), which are given above, can be used. As the electron donor, a substance showing an electron-donating property with respect to the organic compound may be used. Specifically, an alkali metal, an alkaline earth metal, and a rare earth metal are preferable, and lithium, cesium, magnesium, calcium, erbium, and ytterbium are given. In addition, an alkali metal oxide or an alkaline earth metal oxide is preferable, and lithium oxide, calcium oxide, barium oxide, and the like are given. A Lewis base such as magnesium oxide can also be used. An organic compound such as tetrathiafulvalene (abbreviation: TTF) can also be used.

Note that each of the above-described hole-injection layer 111, hole-transport layer 112, light-emitting layer 113, electron-transport layer 114, electron-injection layer 115, and charge-generation layer 116 can be formed by a method such as an evaporation method (e.g., a vacuum evaporation method), an ink-jet method, or a coating method.

In the above-described light-emitting element, current flows due to a potential difference applied between the first electrode 101 and the second electrode 103 and holes and electrons recombine in the EL layer 102, whereby light is emitted. Then, the emitted light is extracted outside through one or both of the first electrode 101 and the second electrode 103. Thus, one or both of the first electrode 101 and the second electrode 103 are electrodes having light-transmitting properties.

The above-described light-emitting element can emit phosphorescence originating from the organometallic iridium complex and thus can have higher efficiency than a light-emitting element using only a fluorescent compound.

The structure described in this embodiment can be used in appropriate combination with the structure described in any of other embodiments.

### Embodiment 3

Described in this embodiment is a light-emitting element (hereinafter, a tandem light-emitting element) with a structure in which the organometallic iridium complex of one embodiment of the present invention is used as an EL material in an EL layer and a charge-generation layer is provided between a plurality of EL layers.

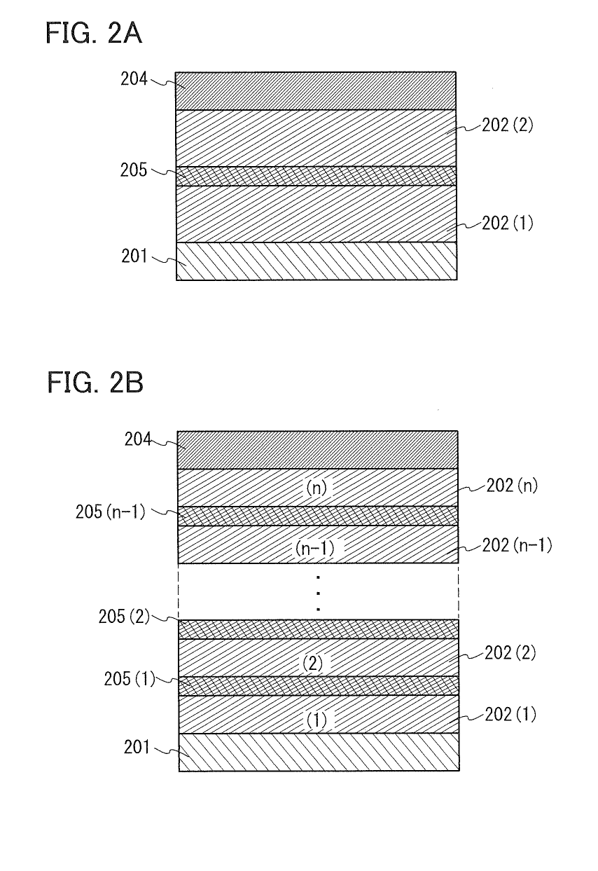

A light-emitting element described in this embodiment is a tandem light-emitting element including a plurality of EL layers (a first EL layer 202(1) and a second EL layer 202(2)) between a pair of electrodes (a first electrode 201 and a second electrode 204), as illustrated in FIG. 2A.

In this embodiment, the first electrode 201 functions as an anode, and the second electrode 204 functions as a cathode. Note that the first electrode 201 and the second electrode 204 can have structures similar to those described in Embodiment 2. In addition, either or both of the EL layers (the first EL layer 202(1) and the second EL layer 202(2)) may have structures similar to those described in Embodiment 2. In other words, the structures of the first EL layer 202(1) and the second EL layer 202(2) may be the same or different from each other and can be similar to those of the EL layers described in Embodiment 2.

In addition, a charge-generation layer 205 is provided between the plurality of EL layers (the first EL layer 202(1) and the second EL layer 202(2)). The charge-generation layer 205 has a function of injecting electrons into one of the EL layers and injecting holes into the other of the EL layers when voltage is applied between the first electrode 201 and the second electrode 204. In this embodiment, when voltage is applied such that the potential of the first electrode 201 is higher than that of the second electrode 204, the charge-generation layer 205 injects electrons into the first EL layer 202(1) and injects holes into the second EL layer 202(2).

Note that in terms of light extraction efficiency, the charge-generation layer 205 preferably has a property of transmitting visible light (specifically, the charge-generation layer 205 has a visible light transmittance of 40% or more). The charge-generation layer 205 functions even when it has lower conductivity than the first electrode 201 or the second electrode 204.

The charge-generation layer 205 may have either a structure in which an electron acceptor (acceptor) is added to an organic compound having a high hole-transport property or a structure in which an electron donor (donor) is added to an organic compound having a high electron-transport property. Alternatively, both of these structures may be stacked.

In the case of the structure in which an electron acceptor is added to an organic compound having a high hole-transport property, as the organic compound having a high hole-transport property, for example, an aromatic amine compound such as NPB, TPD, TDATA, MTDATA, or BSPB, or the like can be used. The substances listed here are mainly ones that have a hole mobility of 1×10⁻⁶ cm²/Vs or higher. Note that any organic compound other than the compounds listed here may be used as long as the hole-transport property is higher than the electron-transport property.

As the electron acceptor, 7,7,8,8-tetracyano-2,3,5,6-tetrafluoroquinodimethane (abbreviation: F₄-TCNQ), chloranil, and the like can be given. Oxides of metals belonging to Groups 4 to 8 of the periodic table can also be given. Specifically, vanadium oxide, niobium oxide, tantalum oxide, chromium oxide, molybdenum oxide, tungsten oxide, manganese oxide, and rhenium oxide are preferable because of their high electron-accepting properties. Among these, molybdenum oxide is especially preferable because it is stable in the air, has a low hygroscopic property, and is easy to handle.

In the case of the structure in which an electron donor is added to an organic compound having a high electron-transport property, as the organic compound having a high electron-transport property, for example, a metal complex having a quinoline skeleton or a benzoquinoline skeleton, such as Alq, Almq₃, BeBq₂, or BAlq, or the like can be used. Alternatively, a metal complex having an oxazole-based ligand or a thiazole-based ligand, such as Zn(BOX)₂ or Zn(BTZ)₂ can be used. Alternatively, in addition to such a metal complex, PBD, OXD-7, TAZ, Bphen, BCP, or the like can be used. The substances listed here are mainly ones that have an electron mobility of 1×10⁻⁶ cm²/Vs or higher. Note that any organic compound other than the compounds listed here may be used as long as the electron-transport property is higher than the hole-transport property.

As the electron donor, it is possible to use an alkali metal, an alkaline earth metal, a rare earth metal, metals belonging to Groups 2 and 13 of the periodic table, or an oxide or carbonate thereof. Specifically, lithium (Li), cesium (Cs), magnesium (Mg), calcium (Ca), ytterbium (Yb), indium (In), lithium oxide, cesium carbonate, or the like is preferably used. Alternatively, an organic compound such as tetrathianaphthacene may be used as the electron donor.

Note that forming the charge-generation layer 205 by using any of the above materials can suppress a drive voltage increase caused by the stack of the EL layers.

Although the light-emitting element including two EL layers is described in this embodiment, the present invention can be similarly applied to a light-emitting element in which n EL layers (202(1) to 202(n)) (n is three or more) are stacked as illustrated in FIG. 2B. In the case where a plurality of EL layers are included between a pair of electrodes as in the light-emitting element according to this embodiment, by providing charge-generation layers (205(1) to 205(n-1)) between the EL layers, light emission in a high luminance region can be obtained with current density kept low. Since the current density can be kept low, the element can have a long lifetime.

When the EL layers have different emission colors, a desired emission color can be obtained from the whole light-emitting element. For example, in a light-emitting element having two EL layers, when an emission color of the first EL layer and an emission color of the second EL layer are complementary colors, the light-emitting element can emit white light as a whole. Note that “complementary colors” refer to colors that can produce an achromatic color when mixed. In other words, mixing light of complementary colors allows white emission to be obtained. Specifically, a combination in which blue light emission is obtained from the first EL layer and yellow light emission or orange light emission is obtained from the second EL layer is given as an example. In that case, it is not necessary that both of blue light emission and yellow (or orange) light emission are fluorescence, and both are not necessarily phosphorescence. For example, a combination in which blue light emission is fluorescence and yellow (or orange) light emission is phosphorescence or a combination in which blue light emission is phosphorescence and yellow (or orange) light emission is fluorescence may be employed.

The same can be applied to a light-emitting element having three EL layers. For example, the light-emitting element as a whole can provide white light emission when the emission color of the first EL layer is red, the emission color of the second EL layer is green, and the emission color of the third EL layer is blue.

Note that the structure described in this embodiment can be combined as appropriate with any of the structures described in other embodiments.

### Embodiment 4

Described in this embodiment is a light-emitting device that includes a light-emitting element in which the organometallic iridium complex of one embodiment of the present invention is used for an EL layer.

The light-emitting device may be either a passive matrix light-emitting device or an active matrix light-emitting device. Any of the light-emitting elements described in other embodiments can be used for the light-emitting device described in this embodiment.

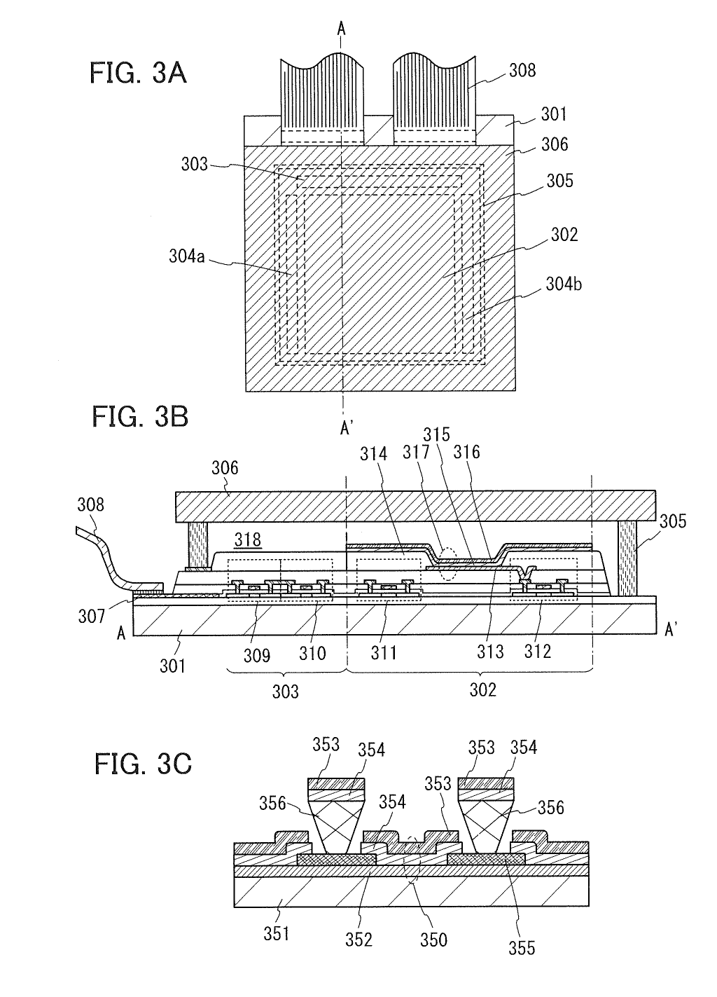

In this embodiment, first, an active matrix light-emitting device is described with reference to FIGS. 3A to 3C.

Note that FIG. 3A is a top view illustrating a light-emitting device and FIG. 3B is a cross-sectional view taken along the chain line A-A′ in FIG. 3A. The active matrix light-emitting device described in this embodiment includes a pixel portion 302 provided over an element substrate 301, a driver circuit portion (a source line driver circuit) 303, and driver circuit portions (gate line driver circuits) 304a and 304b. The pixel portion 302, the driver circuit portion 303, and the driver circuit portions 304a and 304b are sealed between the element substrate 301 and a sealing substrate 306 with a sealant 305.

In addition, over the element substrate 301, a lead wiring 307 for connecting an external input terminal, through which a signal (e.g., a video signal, a clock signal, a start signal, a reset signal, or the like) or electric potential from the outside is transmitted to the driver circuit portion 303 and the driver circuit portions 304a and 304b, is provided. Here, an example is described in which a flexible printed circuit (FPC) 308 is provided as the external input terminal. Although only the FPC is illustrated here, the FPC may be provided with a printed wiring board (PWB). The light-emitting device in this specification includes, in its category, not only the light-emitting device itself but also the light-emitting device provided with the FPC or the PWB.

Next, a cross-sectional structure is described with reference to FIG. 3B. The driver circuit portions and the pixel portion are formed over the element substrate 301; the driver circuit portion 303 that is the source line driver circuit and the pixel portion 302 are illustrated here.

The driver circuit portion 303 is an example in which an FET 309 and an FET 310 are combined. Note that the driver circuit portion 303 may be formed with a circuit including transistors having the same conductivity type (either n-channel transistors or p-channel transistors) or a CMOS circuit including an n-channel transistor and a p-channel transistor. Although this embodiment shows a driver integrated type in which the driver circuit is formed over the substrate, the driver circuit is not necessarily formed over the substrate, and may be formed outside the substrate.

The pixel portion 302 includes a plurality of pixels each of which includes a switching FET 311, a current control FET 312, and a first electrode (anode) 313 which is electrically connected to a wiring (a source electrode or a drain electrode) of the current control FET 312. Although the pixel portion 302 includes two FETs, the switching FET 311 and the current control FET 312, in this embodiment, one embodiment of the present invention is not limited thereto. The pixel portion 302 may include, for example, three or more FETs and a capacitor in combination.

As the FETs 309, 310, 311, and 312, for example, a staggered transistor or an inverted staggered transistor can be used. Examples of a semiconductor material that can be used for the FETs 309, 310, 311, and 312 include a Group 13 semiconductor (e.g., gallium), a Group 14 semiconductor (e.g., silicon), a compound semiconductor, an oxide semiconductor, and an organic semiconductor material. In addition, there is no particular limitation on the crystallinity of the semiconductor material, and an amorphous semiconductor film or a crystalline semiconductor film can be used. In particular, an oxide semiconductor is preferably used for the FETs 309, 310, 311, and 312. Examples of the oxide semiconductor include an In—Ga oxide and an In-M-Zn oxide (M is Al, Ga, Y, Zr, La, Ce, or Nd). For example, an oxide semiconductor material that has an energy gap of 2 eV or more, preferably 2.5 eV or more, further preferably 3 eV or more is used for the FETs 309, 310, 311, and 312, so that the off-state current of the transistors can be reduced.

In addition, an insulator 314 is formed to cover end portions of the first electrode (anode) 313. In this embodiment, the insulator 314 is formed using a positive photosensitive acrylic resin. The first electrode 313 is used as an anode in this embodiment.

The insulator 314 preferably has a curved surface with curvature at an upper end portion or a lower end portion thereof. This enables the coverage with a film to be formed over the insulator 314 to be favorable. The insulator 314 can be formed using, for example, either a negative photosensitive resin or a positive photosensitive resin. The material for the insulator 314 is not limited to an organic compound and an inorganic compound such as silicon oxide, silicon oxynitride, or silicon nitride can also be used.

The light-emitting element 317 has a stacked-layer structure including the first electrode (anode) 313, an EL layer 315, and a second electrode (cathode) 316, and the EL layer 315 includes at least a light-emitting layer. In the EL layer 315, a hole-injection layer, a hole-transport layer, an electron-transport layer, an electron-injection layer, a charge-generation layer, and the like can be provided as appropriate in addition to the light-emitting layer.

For the first electrode (anode) 313, the EL layer 315, and the second electrode (cathode) 316, any of the materials given in Embodiment 2 can be used. Although not illustrated, the second electrode (cathode) 316 is electrically connected to the FPC 308 which is an external input terminal.

Although the cross-sectional view in FIG. 3B illustrates only one light-emitting element 317, a plurality of light-emitting elements are arranged in a matrix in the pixel portion 302. Light-emitting elements that emit light of three kinds of colors (R, G, and B) are selectively formed in the pixel portion 302, whereby a light-emitting device capable of full color display can be obtained. In addition to the light-emitting elements that emit light of three kinds of colors (R, G, and B), for example, light-emitting elements that emit light of white (W), yellow (Y), magenta (M), cyan (C), and the like may be formed. For example, the light-emitting elements that emit light of a plurality of kinds of colors are used in combination with the light-emitting elements that emit light of three kinds of colors (R, G, and B), whereby effects such as an improvement in color purity and a reduction in power consumption can be achieved. Alternatively, the light-emitting device may be capable of full color display by combination with color filters. The light-emitting device may have improved emission efficiency and reduced power consumption by combination with quantum dots.

Furthermore, the sealing substrate 306 is attached to the element substrate 301 with the sealant 305, whereby a light-emitting element 317 is provided in a space 318 surrounded by the element substrate 301, the sealing substrate 306, and the sealant 305. Note that the space 318 may be filled with an inert gas (such as nitrogen and argon) or the sealant 305. In the case where the sealant is applied for attachment of the substrates, one or more of UV treatment, heat treatment, and the like are preferably performed.

An epoxy-based resin or glass frit is preferably used for the sealant 305. The material preferably allows as little moisture and oxygen as possible to penetrate. As the sealing substrate 306, a glass substrate, a quartz substrate, or a plastic substrate formed of fiber-reinforced plastic (FRP), polyvinyl fluoride) (PVF), polyester, acrylic, or the like can be used. In the case where glass frit is used as the sealant, the element substrate 301 and the sealing substrate 306 are preferably glass substrates for high adhesion.

As described above, an active matrix light-emitting device can be obtained.

The light-emitting device including the light-emitting element in which the organometallic iridium complex of one embodiment of the present invention is contained in the EL layer may be of the passive matrix type, instead of the active matrix type described above.

FIG. 3C is a cross-sectional view illustrating a pixel portion of a passive-matrix light-emitting device.

As illustrated in FIG. 3C, a light-emitting element 350 including a first electrode 352, an EL layer 354, and a second electrode 353 is formed over a substrate 351. Note that the first electrode 352 has an island-like shape, and a plurality of the first electrodes 352 are formed in one direction to form a striped pattern. An insulating film 355 is formed over part of the first electrode 352.

A partition 356 formed using an insulating material is provided over the insulating film 355. The sidewalls of the partition 356 slope so that the distance between one sidewall and the other sidewall gradually decreases toward the surface of the substrate. In other words, a cross section taken along the direction of the short side of the partition 356 is trapezoidal, and the base (a side which is in the same direction as a plane direction of the insulating film 355 and in contact with the insulating film 355) is shorter than the upper side (a side which is in the same direction as the plane direction of the insulating film 355 and not in contact with the insulating film 355). By providing the partition 356 in such a manner, a defect of the light-emitting element due to static electricity or the like can be prevented. Note that the insulating film 355 has an opening portion over part of the first electrode 352, and when the EL layer 354 is formed after formation of the partition 356, the EL layer 354 that is in contact with the first electrode 352 in the opening portion is formed.

After formation of the EL layer 354, the second electrode 353 is formed. Thus, the second electrode 353 is formed over the EL layer 354 and in some cases, is formed over the insulating film 355 without contact with the first electrode 352. Note that since the EL layer 354 and the second electrode 353 are formed after formation of the partition 356, the EL layer 354 and the second electrode 353 are also stacked over the partition 356 sequentially.

Note that sealing can be performed by a method similar to that used for the active matrix light-emitting device, and description thereof is not made.

As described above, a passive matrix light-emitting device can be obtained. Note that since the light-emitting element of one embodiment of the present invention has low drive voltage and high reliability, a light-emitting device can have low power consumption and a long lifetime by including this light-emitting element.

Note that in this specification and the like, a transistor or a light-emitting element can be formed using any of a variety of substrates, for example. The type of a substrate is not limited to a certain type. As the substrate, a semiconductor substrate (e.g., a single crystal substrate or a silicon substrate), an SOI substrate, a glass substrate, a quartz substrate, a plastic substrate, a metal substrate, a stainless steel substrate, a substrate including stainless steel foil, a tungsten substrate, a substrate including tungsten foil, a flexible substrate, an attachment film, paper including a fibrous material, a base material film, or the like can be used, for example. As an example of a glass substrate, a barium borosilicate glass substrate, an aluminoborosilicate glass substrate, a soda lime glass substrate, or the like can be given. Examples of the flexible substrate, the attachment film, the base film, and the like are substrates of plastics typified by polyethylene terephthalate (PET), polyethylene naphthalate (PEN), polyether sulfone (PES), and polytetrafluoroethylene (PTFE). Another example is a synthetic resin such as acrylic. Alternatively, polypropylene, polyester, polyvinyl fluoride, polyvinyl chloride, or the like can be used. Alternatively, polyamide, polyimide, aramid, epoxy, an inorganic vapor deposition film, paper, or the like can be used. Specifically, the use of semiconductor substrates, single crystal substrates, SOI substrates, or the like enables the manufacture of small-sized transistors with a small variation in characteristics, size, shape, or the like and with high current supply capability. A circuit using such transistors achieves lower power consumption of the circuit or higher integration of the circuit.

Alternatively, a flexible substrate may be used as the substrate, and the transistor or the light-emitting element may be provided directly on the flexible substrate. Still alternatively, a separation layer may be provided between the substrate and the transistor or the light-emitting element. The separation layer can be used when part or the whole of a semiconductor device formed over the separation layer is separated from the substrate and transferred onto another substrate. In such a case, the transistor or the light-emitting element can be transferred to a substrate having low heat resistance or a flexible substrate. For the separation layer, a stack including inorganic films, which are a tungsten film and a silicon oxide film, or an organic resin film of polyimide or the like formed over a substrate can be used, for example.

In other words, a transistor or a light-emitting element may be formed using one substrate, and then transferred to another substrate. Examples of a substrate to which a transistor or a light-emitting element is transferred include, in addition to the above-described substrates over which transistors or light-emitting elements can be formed, a paper substrate, a cellophane substrate, an aramid film substrate, a polyimide film substrate, a stone substrate, a wood substrate, a cloth substrate (including a natural fiber (e.g., silk, cotton, and hemp), a synthetic fiber (e.g., nylon, polyurethane, and polyester), a regenerated fiber (e.g., acetate, cupra, rayon, and regenerated polyester), and the like), a leather substrate, and a rubber substrate. When such a substrate is used, a transistor with excellent characteristics or a transistor with low power consumption can be formed, a device with high durability or high heat resistance can be provided, or a reduction in weight or thickness can be achieved.

Note that the structure described in this embodiment can be combined as appropriate with any of the structures described in other embodiments.

### Embodiment 5

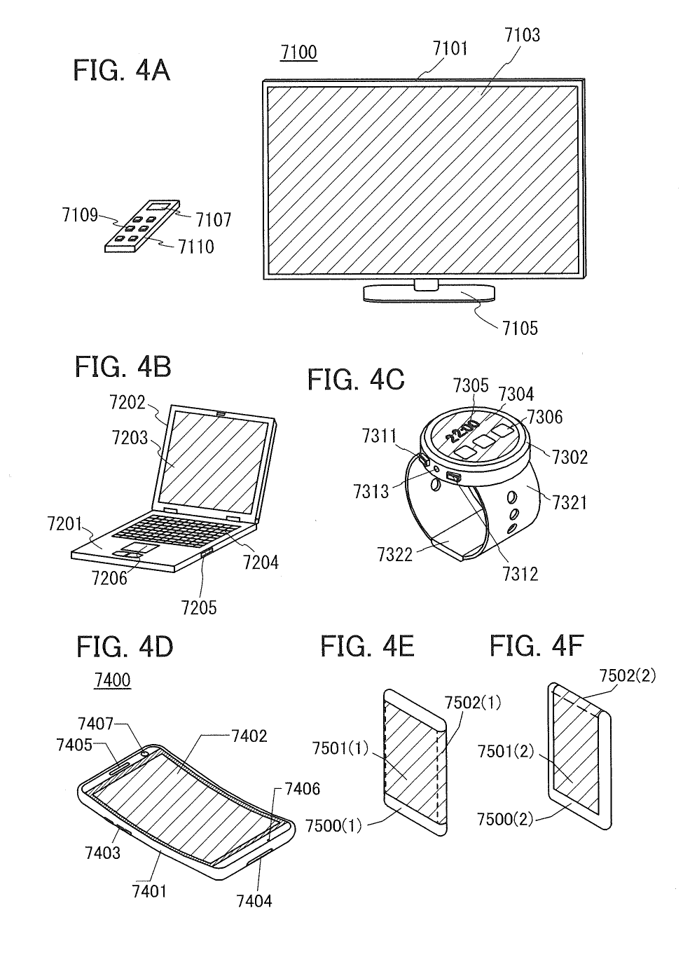

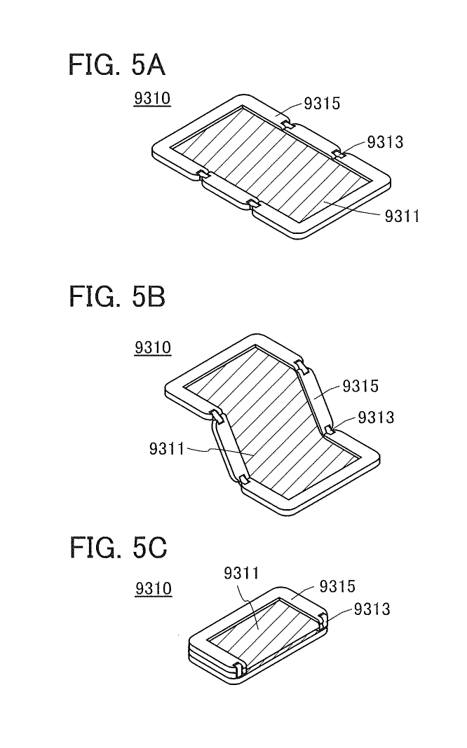

In this embodiment, examples of an electronic device manufactured using a light-emitting device which is one embodiment of the present invention are described with reference to FIGS. 4A to 4D, 4D′-1, and 4D′-2 and FIGS. 5A to 5C.

Examples of the electronic device including the light-emitting device are television devices (also referred to as TV or television receivers), monitors for computers and the like, cameras such as digital cameras and digital video cameras, digital photo frames, cellular phones (also referred to as portable telephone devices), portable game consoles, portable information terminals, audio playback devices, large game machines such as pachinko machines, and the like. Specific examples of the electronic devices are illustrated in FIGS. 4A to 4D, 4D′-1, and 4D′-2.

FIG. 4A illustrates an example of a television device. In the television device 7100, a display portion 7103 is incorporated in a housing 7101. The display portion 7103 can display images and may be a touch panel (an input/output device) including a touch sensor (an input device). Note that the light-emitting device which is one embodiment of the present invention can be used for the display portion 7103. In addition, here, the housing 7101 is supported by a stand 7105.

The television device 7100 can be operated by an operation switch of the housing 7101 or a separate remote controller 7110. With operation keys 7109 of the remote controller 7110, channels and volume can be controlled and images displayed on the display portion 7103 can be controlled. Furthermore, the remote controller 7110 may be provided with a display portion 7107 for displaying data output from the remote controller 7110.

Note that the television device 7100 is provided with a receiver, a modem, and the like. With the use of the receiver, general television broadcasts can be received. Moreover, when the television device is connected to a communication network with or without wires via the modem, one-way (from a sender to a receiver) or two-way (between a sender and a receiver or between receivers) information communication can be performed.

FIG. 4B illustrates a computer, which includes a main body 7201, a housing 7202, a display portion 7203, a keyboard 7204, an external connection port 7205, a pointing device 7206, and the like. Note that this computer can be manufactured using the light-emitting device which is one embodiment of the present invention for the display portion 7203. The display portion 7203 may be a touch panel (an input/output device) including a touch sensor (an input device).

FIG. 4C illustrates a smart watch, which includes a housing 7302, a display panel 7304, operation buttons 7311 and 7312, a connection terminal 7313, a band 7321, a clasp 7322, and the like.

The display panel 7304 mounted in the housing 7302 serving as a bezel includes a non-rectangular display region. The display panel 7304 can display an icon 7305 indicating time, another icon 7306, and the like. The display panel 7304 may be a touch panel (an input/output device) including a touch sensor (an input device).

The smart watch illustrated in FIG. 4C can have a variety of functions, such as a function of displaying a variety of information (e.g., a still image, a moving image, and a text image) on a display portion, a touch panel function, a function of controlling processing with a variety of software (programs), a wireless communication function, and a function of storing data.

The housing 7302 can include a speaker, a sensor (a sensor having a function of measuring or sensing force, displacement, position, speed, acceleration, angular velocity, rotational frequency, distance, light, liquid, magnetism, temperature, chemical substance, sound, hardness, electric field, current, voltage, electric power, radiation, humidity, gradient, oscillation, odor, or infrared rays), a microphone, and the like. Note that the smart watch can be manufactured using the light-emitting device for the display panel 7304.

FIGS. 4D, 4D′-1, and 4D′-2 illustrate an example of a cellular phone (e.g., smartphone). A cellular phone 7400 includes a housing 7401 provided with a display portion 7402, a microphone 7406, a speaker 7405, a camera 7407, an external connection portion 7404, an operation button 7403, and the like. In the case where a light-emitting device is manufactured by forming a light-emitting element of one embodiment of the present invention over a flexible substrate, the light-emitting element can be used for the display portion 7402 having a curved surface as illustrated in FIG. 4D.

When the display portion 7402 of the cellular phone 7400 illustrated in FIG. 4D is touched with a finger or the like, data can be input to the cellular phone 7400. In addition, operations such as making a call and composing e-mail can be performed by touch on the display portion 7402 with a finger or the like.

There are mainly three screen modes of the display portion 7402. The first mode is a display mode mainly for displaying an image. The second mode is an input mode mainly for inputting data such as characters. The third mode is a display-and-input mode in which two modes of the display mode and the input mode are combined.

For example, in the case of making a call or creating e-mail, a character input mode mainly for inputting characters is selected for the display portion 7402 so that characters displayed on the screen can be input. In this case, it is preferable to display a keyboard or number buttons on almost the entire screen of the display portion 7402.

When a detection device such as a gyroscope or an acceleration sensor is provided inside the cellular phone 7400, display on the screen of the display portion 7402 can be automatically changed by determining the orientation of the cellular phone 7400 (whether the cellular phone is placed horizontally or vertically for a landscape mode or a portrait mode).

The screen modes are changed by touch on the display portion 7402 or operation with the operation button 7403 of the housing 7401. The screen modes can be switched depending on the kind of images displayed on the display portion 7402. For example, when a signal of an image displayed on the display portion is a signal of moving image data, the screen mode is switched to the display mode. When the signal is a signal of text data, the screen mode is switched to the input mode.

Moreover, in the input mode, if a signal detected by an optical sensor in the display portion 7402 is detected and the input by touch on the display portion 7402 is not performed for a certain period, the screen mode may be controlled so as to be changed from the input mode to the display mode.

The display portion 7402 may function as an image sensor. For example, an image of a palm print, a fingerprint, or the like is taken by touch on the display portion 7402 with the palm or the finger, whereby personal authentication can be performed. In addition, by providing a backlight or a sensing light source that emits near-infrared light in the display portion, an image of a finger vein, a palm vein, or the like can be taken.

The light-emitting device can be used for a cellular phone having a structure illustrated in FIG. 4E or FIG. 4F, which is another structure of the cellular phone (e.g., smartphone).

Note that in the case of the structure illustrated in FIG. 4E or FIG. 4F, text data, image data, or the like can be displayed on second screens 7502(1) and 7502(2) of housings 7500(1) and 7500(2) as well as first screens 7501(1) and 7501(2). Such a structure enables a user to easily see text data, image data, or the like displayed on the second screens 7502(1) and 7502(2) while the cellular phone is placed in user's breast pocket.

FIGS. 5A to 5C illustrate a foldable portable information terminal 9310. FIG. 5A illustrates the portable information terminal 9310 which is opened. FIG. 5B illustrates the portable infoiination terminal 9310 which is being opened or being folded. FIG. 5C illustrates the portable information terminal 9310 that is folded. The portable information terminal 9310 is highly portable when folded. The portable information terminal 9310 is highly browsable when opened because of a seamless large display region.

A display panel 9311 is supported by three housings 9315 joined together by hinges 9313. Note that the display panel 9311 may be a touch panel (an input/output device) including a touch sensor (an input device). By bending the display panel 9311 at a connection portion between two housings 9315 with the use of the hinges 9313, the portable information terminal 9310 can be reversibly changed in shape from an opened state to a folded state. A light-emitting device of one embodiment of the present invention can be used for the display panel 9311. A display region 9312 in the display panel 9311 is a display region that is positioned at a side surface of the portable information terminal 9310 that is folded. On the display region 9312, information icons, file shortcuts of frequently used applications or programs, and the like can be displayed, and confirmation of information and start of application can be smoothly performed.

As described above, the electronic devices can be obtained using the light-emitting device which is one embodiment of the present invention. Note that since the light-emitting element of one embodiment of the present invention has low drive voltage and high reliability, an electronic device can have low power consumption and a long lifetime by including the light-emitting device that includes the light-emitting element. The light-emitting device can be used for electronic devices in a variety of fields without being limited to the electronic devices described in this embodiment.

Note that the structure described in this embodiment can be combined as appropriate with any of the structures described in other embodiments.

### Embodiment 6

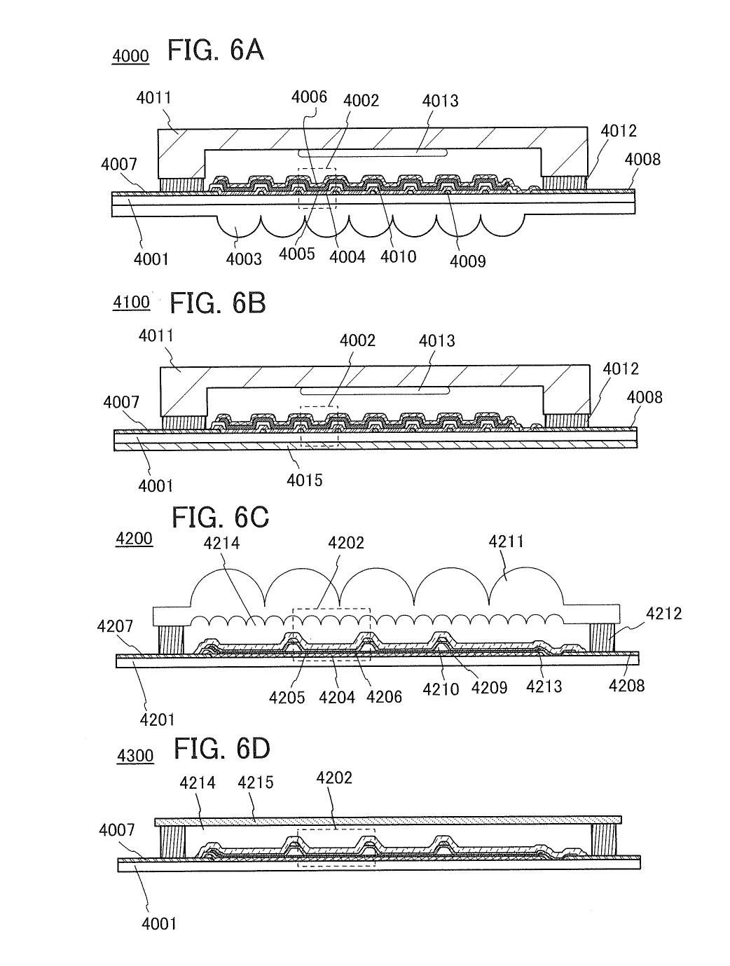

In this embodiment, a structure of a lighting device fabricated using the light-emitting element of one embodiment of the present invention will be described with reference to FIGS. 6A to 6D.

FIGS. 6A to 6D are examples of cross-sectional views of lighting devices. FIGS. 6A and 6B illustrate bottom-emission lighting devices in which light is extracted from the substrate side, and FIGS. 6C and 6D illustrate top-emission lighting devices in which light is extracted from the sealing substrate side.

A lighting device 4000 illustrated in FIG. 6A includes a light-emitting element 4002 over a substrate 4001. In addition, the lighting device 4000 includes a substrate 4003 with unevenness on the outside of the substrate 4001. The light-emitting element 4002 includes a first electrode 4004, an EL layer 4005, and a second electrode 4006.

The first electrode 4004 is electrically connected to an electrode 4007, and the second electrode 4006 is electrically connected to an electrode 4008. In addition, an auxiliary wiring 4009 electrically connected to the first electrode 4004 may be provided. Note that an insulating layer 4010 is formed over the auxiliary wiring 4009.

The substrate 4001 and a sealing substrate 4011 are bonded to each other by a sealant 4012. A desiccant 4013 is preferably provided between the sealing substrate 4011 and the light-emitting element 4002. The substrate 4003 has the unevenness illustrated in FIG. 6A, whereby the extraction efficiency of light emitted from the light-emitting element 4002 can be increased.

Instead of the substrate 4003, a diffusion plate 4015 may be provided on the outside of a substrate 4001 as in a lighting device 4100 illustrated in FIG. 6B.

A lighting device 4200 illustrated in FIG. 6C includes a light-emitting element 4202 over a substrate 4201. The light-emitting element 4202 includes a first electrode 4204, an EL layer 4205, and a second electrode 4206.

The first electrode 4204 is electrically connected to an electrode 4207, and the second electrode 4206 is electrically connected to an electrode 4208. An auxiliary wiring 4209 electrically connected to the second electrode 4206 may be provided. An insulating layer 4210 may be provided under the auxiliary wiring 4209.

The substrate 4201 and a sealing substrate 4211 with unevenness are bonded to each other by a sealant 4212. A barrier film 4213 and a planarization film 4214 may be provided between the sealing substrate 4211 and the light-emitting element 4202. The sealing substrate 4211 has the unevenness illustrated in FIG. 6C, whereby the extraction efficiency of light emitted from the light-emitting element 4202 can be increased.

Instead of the sealing substrate 4211, a diffusion plate 4215 may be provided over the light-emitting element 4202 as in a lighting device 4300 illustrated in FIG. 6D.

Note that the EL layers 4005 and 4205 in this embodiment can include the organometallic iridium complex of one embodiment of the present invention. In that case, a lighting device with low power consumption can be provided.

Note that the structure described in this embodiment can be combined as appropriate with any of the structures described in other embodiments.

### Embodiment 7

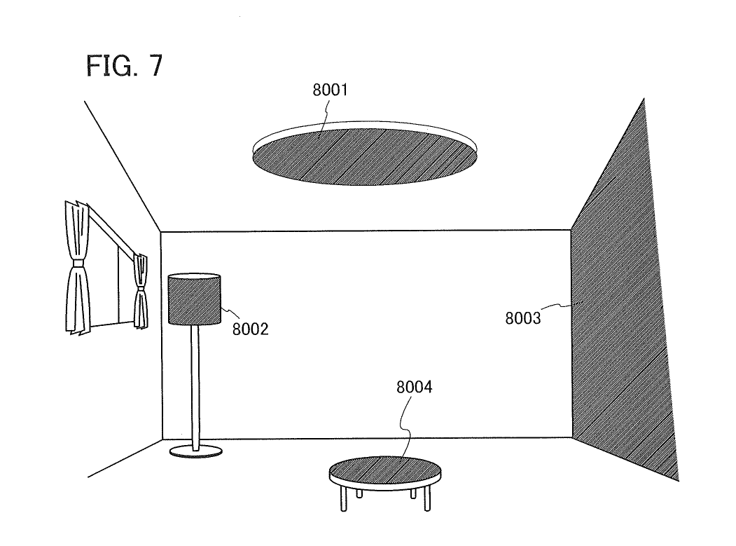

In this embodiment, examples of a lighting device that is an application of the light-emitting device in Embodiment 4 are described with reference to FIG. 7.

FIG. 7 illustrates an example in which the light-emitting device is used as an indoor lighting device 8001. Since the light-emitting device can have a large area, it can be used for a lighting device having a large area. In addition, with the use of a housing with a curved surface, a lighting device 8002 in which a light-emitting region has a curved surface can also be obtained. A light-emitting element included in the light-emitting device described in this embodiment is in a thin film form, which allows the housing to be designed more freely. Therefore, the lighting device may include a cover or a support and can be elaborately designed in a variety of ways. In addition, a wall of the room may be provided with a large-sized lighting device 8003.

When the light-emitting device is used for a surface of a table, a lighting device 8004 that has a function as a table can be obtained. When the light-emitting device is used as part of other furniture, a lighting device that functions as the furniture can be obtained.

As described above, a variety of lighting devices that include the light-emitting device can be obtained. Note that since the light-emitting element of one embodiment of the present invention has low drive voltage and high reliability, a lighting device can have low power consumption and a long lifetime by including this light-emitting element. These lighting devices are also embodiments of the present invention.

Note that the structure described in this embodiment can be combined as appropriate with any of the structures described in other embodiments.

### Embodiment 8

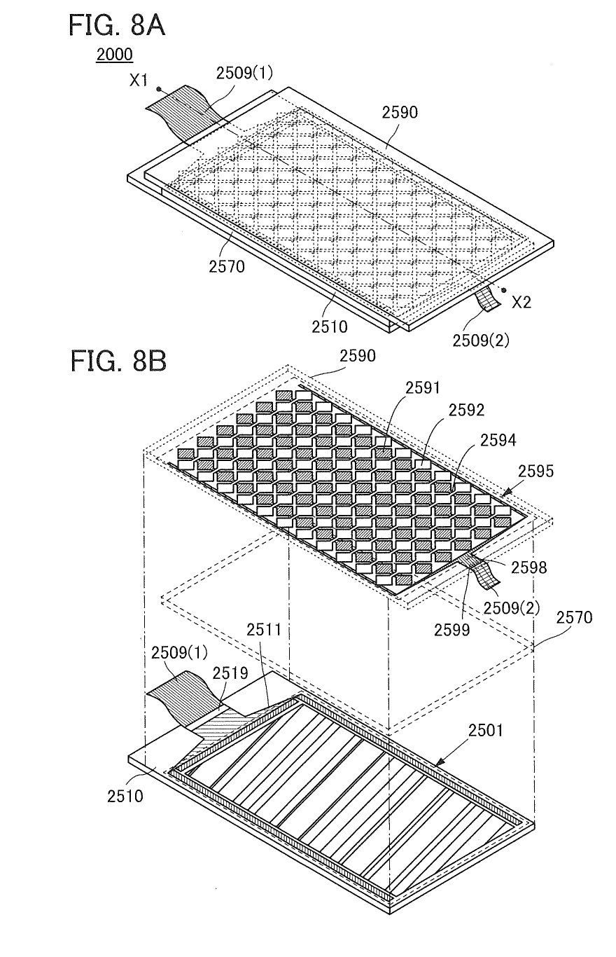

In this embodiment, touch panels including a light-emitting element of one embodiment of the present invention or a light-emitting device of one embodiment of the present invention will be described with reference to FIGS. 8A and 8B, FIGS. 9A and 9B, FIGS. 10A and 10B, FIGS. 11A and 11B, and FIG. 12.

FIGS. 8A and 8B are perspective views of a touch panel 2000. Note that FIGS. 8A and 8B illustrate typical components of the touch panel 2000 for simplicity.

The touch panel 2000 includes a display panel 2501 and a touch sensor 2595 (see FIG. 8B). Furthermore, the touch panel 2000 includes a substrate 2510, a substrate 2570, and a substrate 2590.

The display panel 2501 includes a plurality of pixels over the substrate 2510, and a plurality of wirings 2511 through which signals are supplied to the pixels. The plurality of wirings 2511 are led to a peripheral portion of the substrate 2510, and part of the plurality of wirings 2511 forms a terminal 2519. The terminal 2519 is electrically connected to an FPC 2509(1).

The substrate 2590 includes the touch sensor 2595 and a plurality of wirings 2598 electrically connected to the touch sensor 2595. The plurality of wirings 2598 are led to a peripheral portion of the substrate 2590, and part of the plurality of wirings 2598 forms a terminal 2599. The terminal 2599 is electrically connected to an FPC 2509(2). Note that in FIG. 8B, electrodes, wirings, and the like of the touch sensor 2595 provided on the back side of the substrate 2590 (the side facing the substrate 2510) are indicated by solid lines for clarity.

As the touch sensor 2595, a capacitive touch sensor can be used, for example. Examples of the capacitive touch sensor are a surface capacitive touch sensor and a projected capacitive touch sensor.

Examples of the projected capacitive touch sensor are a self-capacitive touch sensor and a mutual capacitive touch sensor, which differ mainly in the driving method. The use of a mutual capacitive touch sensor is preferable because multiple points can be sensed simultaneously.

First, an example of using a projected capacitive touch sensor will be described below with reference to FIG. 8B. Note that in the case of a projected capacitive touch sensor, a variety of sensors that can sense the closeness or the contact of a sensing target such as a finger can be used.

The projected capacitive touch sensor 2595 includes electrodes 2591 and electrodes 2592. The electrodes 2591 are electrically connected to any of the plurality of wirings 2598, and the electrodes 2592 are electrically connected to any of the other wirings 2598. The electrodes 2592 each have a shape of a plurality of quadrangles arranged in one direction with one corner of a quadrangle connected to one corner of another quadrangle with a wiring 2594 in one direction as illustrated in FIGS. 8A and 8B. In the same manner, the electrodes 2591 each have a shape of a plurality of quadrangles arranged with one corner of a quadrangle connected to one corner of another quadrangle; however, the direction in which the electrodes 2591 are connected is a direction crossing the direction in which the electrodes 2592 are connected. Note that the direction in which the electrodes 2591 are connected and the direction in which the electrodes 2592 are connected are not necessarily perpendicular to each other, and the electrodes 2591 may be arranged to intersect with the electrodes 2592 at an angle greater than 0° and less than 90°.

The intersecting area of the wiring 2594 and one of the electrodes 2592 is preferably as small as possible. Such a structure allows a reduction in the area of a region where the electrodes are not provided, reducing unevenness in transmittance. As a result, unevenness in the luminance of light from the touch sensor 2595 can be reduced.

Note that the shapes of the electrodes 2591 and the electrodes 2592 are not limited to the above-mentioned shapes and can be any of a variety of shapes. For example, the plurality of electrodes 2591 may be provided so that space between the electrodes 2591 are reduced as much as possible, and the plurality of electrodes 2592 may be provided with an insulating layer sandwiched between the electrodes 2591 and the electrodes 2592. In that case, between two adjacent electrodes 2592, a dummy electrode which is electrically insulated from these electrodes is preferably provided, whereby the area of a region having a different transmittance can be reduced.

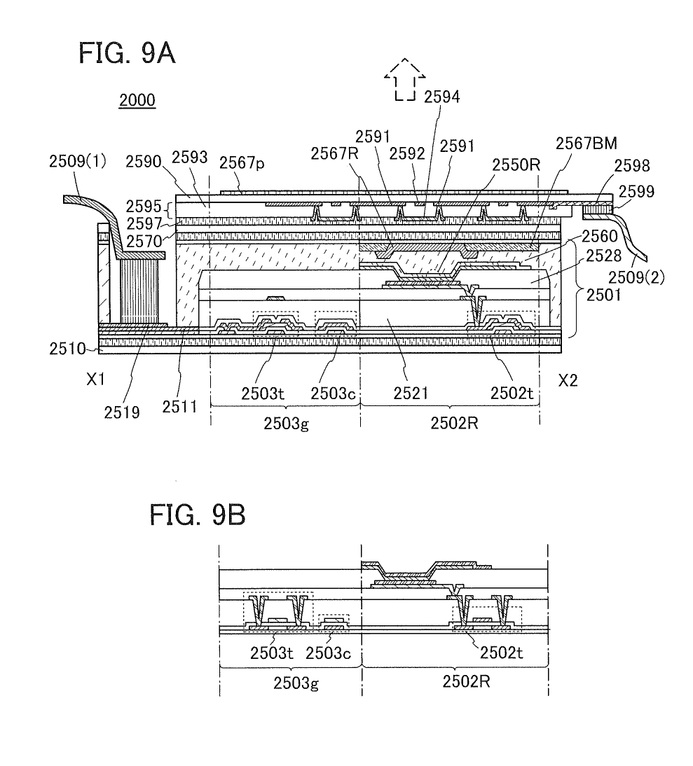

Next, the touch panel 2000 will be described in detail with reference to FIGS. 9A and 9B. FIGS. 9A and 9B are cross-sectional views taken along dashed-dotted line X1-X2 in FIG. 8A.

The touch panel 2000 includes the touch sensor 2595 and the display panel 2501.

The touch sensor 2595 includes the electrodes 2591 and the electrodes 2592 that are provided in a staggered arrangement and in contact with the substrate 2590, an insulating layer 2593 covering the electrodes 2591 and the electrodes 2592, and the wiring 2594 that electrically connects the adjacent electrodes 2591 to each other. Between the adjacent electrodes 2591, the electrode 2592 is provided.

The electrodes 2591 and the electrodes 2592 can be formed using a light-transmitting conductive material. As a light-transmitting conductive material, a conductive oxide such as indium oxide, indium tin oxide, indium zinc oxide, zinc oxide, or zinc oxide to which gallium is added can be used. A graphene compound may be used as well. When a graphene compound is used, it can be formed, for example, by reducing a graphene oxide film. As a reducing method, a method with application of heat, a method with laser irradiation, or the like can be employed.

For example, the electrodes 2591 and the electrodes 2592 can be formed by depositing a light-transmitting conductive material on the substrate 2590 by a sputtering method and then removing an unneeded portion by any of various patterning techniques such as photolithography.

Examples of a material for the insulating layer 2593 are a resin such as acrylic or epoxy resin, a resin having a siloxane bond, and an inorganic insulating material such as silicon oxide, silicon oxynitride, or aluminum oxide.

The adjacent electrodes 2591 are electrically connected to each other with a wiring 2594 formed in part of the insulating layer 2593. Note that a material for the wiring 2594 preferably has higher conductivity than materials for the electrode 2591 and the electrode 2592 to reduce electrical resistance.

One wiring 2598 is electrically connected to any of the electrodes 2591 and 2592. Part of the wiring 2598 serves as a terminal. For the wiring 2598, a metal material such as aluminum, gold, platinum, silver, nickel, titanium, tungsten, chromium, molybdenum, iron, cobalt, copper, or palladium or an alloy material containing any of these metal materials can be used.

Through the terminal 2599, the wiring 2598 and the FPC 2509(2) are electrically connected to each other. The terminal 2599 can be formed using any of various kinds of anisotropic conductive films (ACF), anisotropic conductive pastes (ACP), and the like.

An adhesive layer 2597 is provided in contact with the wiring 2594. That is, the touch sensor 2595 is attached to the display panel 2501 so that they overlap with each other with the adhesive layer 2597 provided therebetween. Note that the substrate 2570 as shown in FIG. 9A may be provided over the surface of the display panel 2501 that is adjacent to the adhesive layer 2597; however, the substrate 2570 is not always needed.

The adhesive layer 2597 has a light-transmitting property. For example, a thermosetting resin or an ultraviolet curable resin can be used; specifically, a resin such as an acrylic-based resin, a urethane-based resin, an epoxy-based resin, or a siloxane-based resin can be used.

The display panel 2501 in FIG. 9A includes, between the substrate 2510 and the substrate 2570, a plurality of pixels arranged in a matrix and a driver circuit. Each pixel includes a light-emitting element and a pixel circuit driving the light-emitting element.

In FIG. 9A, a pixel 2502R is shown as an example of the pixel of the display panel 2501, and a scan line driver circuit 2503g is shown as an example of the driver circuit.

The pixel 2502R includes a light-emitting element 2550R and a transistor 2502t that can supply electric power to the light-emitting element 2550R.

The transistor 2502t is covered with the insulating layer 2521. The insulating layer 2521 covers unevenness caused by the transistor and the like that have been already formed to provide a flat surface. The insulating layer 2521 may serve also as a layer for preventing diffusion of impurities. That is preferable because a reduction in the reliability of the transistor or the like due to diffusion of impurities can be prevented.

The light-emitting element 2550R is electrically connected to the transistor 2502t through a wiring. It is one electrode of the light-emitting element 2550R that is directly connected to the wiring. An end portion of the one electrode of the light-emitting element 2550R is covered with an insulator 2528.

The light-emitting element 2550R includes an EL layer between a pair of electrodes. A coloring layer 2567R is provided to overlap with the light-emitting element 2550R, and part of light emitted from the light-emitting element 2550R is transmitted through the coloring layer 2567R and extracted in the direction indicated by an arrow in the drawing. A light-blocking layer 2567BM is provided at an end portion of the coloring layer, and a sealing layer 2560 is provided between the light-emitting element 2550R and the coloring layer 2567R.

Note that when the sealing layer 2560 is provided on the side from which light from the light-emitting element 2550R is extracted, the sealing layer 2560 preferably has a light-transmitting property. The sealing layer 2560 preferably has a higher refractive index than the air.

A scan line driver circuit 2503g includes a transistor 2503t and a capacitor 2503c. Note that the driver circuit and the pixel circuits can be formed in the same process over the same substrate. Thus, similarly to the transistor 2502t in the pixel circuit, the transistor 2503t in the driver circuit (scan line driver circuit 2503g) is also covered with the insulating layer 2521.

The wirings 2511 through which a signal can be supplied to the transistor 2503t are provided. The terminal 2519 is provided in contact with the wiring 2511. The terminal 2519 is electrically connected to the FPC 2509(1), and the FPC 2509(1) has a function of supplying signals such as a pixel signal and a synchronization signal. Note that a printed wiring board (PWB) may be attached to the FPC 2509(1).

Although the case where the display panel 2501 shown in FIG. 9A includes a bottom-gate transistor is described, the structure of the transistor is not limited thereto, and any of transistors with various structures can be used. In each of the transistor 2502t and the transistor 2503t illustrated in FIG. 9A, a semiconductor layer including an oxide semiconductor can be used for a channel region. Alternatively, a semiconductor layer containing amorphous silicon or a semiconductor layer containing polycrystalline silicon that is obtained by crystallization process such as laser annealing can be used for a channel region.

FIG. 9B illustrates the structure of the display panel 2501 that includes a top-gate transistor instead of the bottom-gate transistor illustrated in FIG. 9A. The kind of the semiconductor layer that can be used for the channel region does not depend on the structure of the transistor.

In the touch panel 2000 shown in FIG. 9A, an anti-reflection layer 2567p overlapping with at least the pixel is preferably provided on a surface of the touch panel on the side from which light from the pixel is extracted, as shown in FIG. 9A. As the anti-reflection layer 2567p, a circular polarizing plate or the like can be used.

For the substrate 2510, the substrate 2570, and the substrate 2590 in FIG. 9A, for example, a flexible material having a vapor permeability of 1×10⁻⁵ g/(m²·day) or lower, preferably 1×10⁻⁶ g/(m²·day) or lower can be favorably used. Alternatively, it is preferable to use the materials that make these substrates have substantially the same coefficient of thermal expansion. For example, the coefficients of linear expansion of the materials are 1×10⁻³/K or lower, preferably 5×10⁻⁵/K or lower, and further preferably 1×10⁻⁵/K or lower.

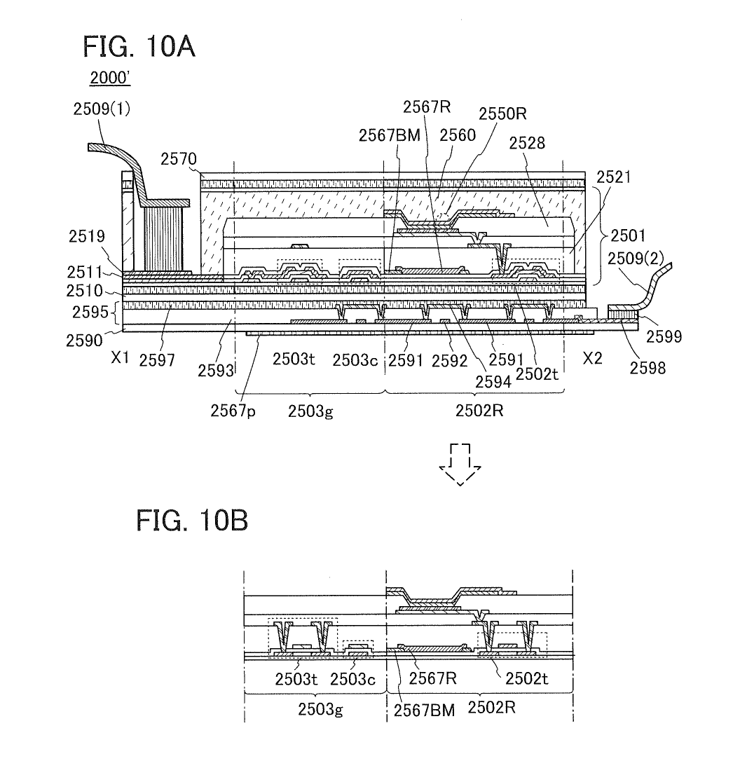

Next, a touch panel 2000′ having a structure different from that of the touch panel 2000 shown in FIGS. 9A and 9B is described with reference to FIGS. 10A and 10B. Note that the touch panel 2000′ can be used for an application similar to that of the touch panel 2000.

FIGS. 10A and 10B are cross-sectional views of the touch panel 2000′. In the touch panel 2000′ illustrated in FIGS. 10A and 10B, the position of the touch sensor 2595 relative to the display panel 2501 is different from that in the touch panel 2000 illustrated in FIGS. 9A and 9B. Only different structures will be described below, and the above description of the touch panel 2000 can be referred to for the other similar structures.

The coloring layer 2567R overlaps with the light-emitting element 2550R. Light from the light-emitting element 2550R illustrated in FIG. 10A is emitted to the side where the transistor 2502t is provided. That is, (part of) light emitted from the light-emitting element 2550R passes through the coloring layer 2567R and is extracted in the direction indicated by an arrow in FIG. 10A. Note that the light-blocking layer 2567BM is provided at an end portion of the coloring layer 2567R.

The touch sensor 2595 is provided on the side of the display panel 2501 that is closer to the transistor 2502t than to the light-emitting element 2550R (see FIG. 10A).

The adhesive layer 2597 is in contact with the substrate 2510 of the display panel 2501 and attaches the display panel 2501 and the touch sensor 2595 to each other in the structure shown in FIG. 10A. The substrate 2510 is not necessarily provided between the display panel 2501 and the touch sensor 2595 that are attached to each other by the adhesive layer 2597.

As in the touch panel 2000, transistors with a variety of structures can be used for the display panel 2501 in the touch panel 2000′. Although a bottom-gate transistor is used in FIG. 10A, a top-gate transistor may be applied as shown in FIG. 10B.

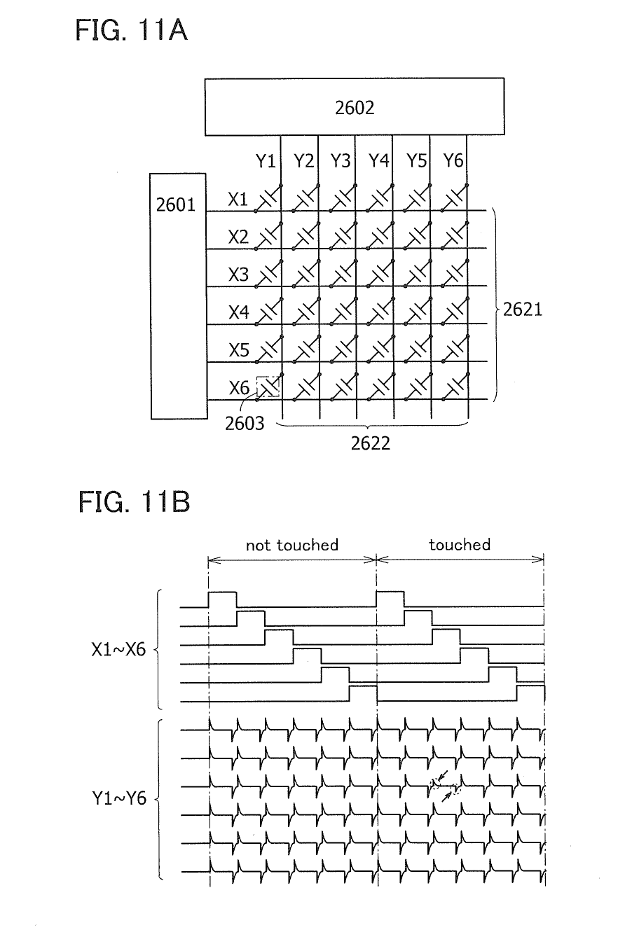

Then, an example of a driving method of the touch panel will be described with reference to FIGS. 11A and 11B.

FIG. 11A is a block diagram illustrating the structure of a mutual capacitive touch sensor. FIG. 11A illustrates a pulse voltage output circuit 2601 and a current sensing circuit 2602. Note that in the example of FIG. 11A, six wirings X1-X6 represent electrodes 2621 to which a pulse voltage is supplied, and six wirings Y1-Y6 represent electrodes 2622 that sense a change in current. FIG. 11A also illustrates a capacitor 2603 that is formed in a region where the electrodes 2621 and 2622 overlap with each other. Note that functional replacement between the electrodes 2621 and 2622 is possible.

The pulse voltage output circuit 2601 is a circuit for sequentially applying a pulse voltage to the wirings X1 to X6. By application of a pulse voltage to the wirings X1 to X6, an electric field is generated between the electrodes 2621 and 2622 of the capacitor 2603. When the electric field between the electrodes is shielded, for example, a change occurs in the capacitor 2603 (mutual capacitance). The approach or contact of a sensing target can be sensed by utilizing this change.

The current sensing circuit 2602 is a circuit for sensing changes in current flowing through the wirings Y1 to Y6 that are caused by the change in mutual capacitance in the capacitor 2603. No change in current value is sensed in the wirings Y1 to Y6 when there is no approach or contact of a sensing target, whereas a decrease in current value is sensed when mutual capacitance is decreased owing to the approach or contact of a sensing target. Note that an integrator circuit or the like is used for sensing of current.

FIG. 11B is a timing chart showing input and output waveforms in the mutual capacitive touch sensor illustrated in FIG. 11A. In FIG. 11B, sensing of a sensing target is performed in all the rows and columns in one frame period. FIG. 11B shows a period when a sensing target is not sensed (not touched) and a period when a sensing target is sensed (touched). Sensed current values of the wirings Y1 to Y6 are shown as the waveforms of voltage values.

A pulse voltage is sequentially applied to the wirings X1 to X6, and the waveforms of the wirings Y1 to Y6 change in accordance with the pulse voltage. When there is no approach or contact of a sensing target, the waveforms of the wirings Y1 to Y6 change in accordance with changes in the voltages of the wirings X1 to X6. The current value is decreased at the point of approach or contact of a sensing target and accordingly the waveform of the voltage value changes. By sensing a change in mutual capacitance in this manner, the approach or contact of a sensing target can be sensed.

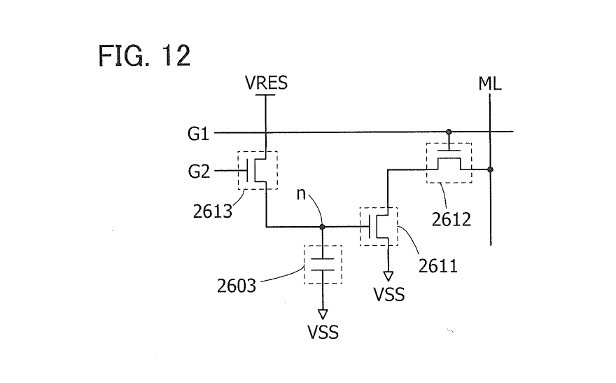

Although FIG. 11A illustrates a passive touch sensor in which only the capacitor 2603 is provided at the intersection of wirings as a touch sensor, an active touch sensor including a transistor and a capacitor may be used. FIG. 12 is a sensor circuit included in an active touch sensor.

The sensor circuit illustrated in FIG. 12 includes the capacitor 2603, a transistor 2611, a transistor 2612, and a transistor 2613.

A signal G2 is input to a gate of the transistor 2613. A voltage VRES is applied to one of a source and a drain of the transistor 2613, and one electrode of the capacitor 2603 and a gate of the transistor 2611 are electrically connected to the other of the source and the drain of the transistor 2613. One of a source and a drain of the transistor 2611 is electrically connected to one of a source and a drain of the transistor 2612, and a voltage VSS is applied to the other of the source and the drain of the transistor 2611. A signal G1 is input to a gate of the transistor 2612, and a wiring ML is electrically connected to the other of the source and the drain of the transistor 2612. The voltage VSS is applied to the other electrode of the capacitor 2603.

Next, the operation of the sensor circuit illustrated in FIG. 12 will be described. First, a potential for turning on the transistor 2613 is supplied as the signal G2, and a potential with respect to the voltage VRES is thus applied to the node n connected to the gate of the transistor 2611. Then, a potential for turning off the transistor 2613 is applied as the signal G2, whereby the potential of the node n is maintained. Then, mutual capacitance of the capacitor 2603 changes owing to the approach or contact of a sensing target such as a finger, and accordingly the potential of the node n is changed from VRES.

In reading operation, a potential for turning on the transistor 2612 is supplied as the signal G1. A current flowing through the transistor 2611, that is, a current flowing through the wiring ML is changed in accordance with the potential of the node n. By sensing this current, the approach or contact of a sensing target can be sensed.

In each of the transistors 2611, 2612, and 2613, an oxide semiconductor layer is preferably used as a semiconductor layer in which a channel region is formed. In particular, such a transistor is preferably used as the transistor 2613 so that the potential of the node n can be held for a long time and the frequency of operation of resupplying VRES to the node n (refresh operation) can be reduced.

At least part of this embodiment can be implemented in combination with any of other embodiments described in this specification as appropriate.

### EXAMPLE 1

### SYNTHESIS EXAMPLE 1

In Example 1, a synthesis method of a high-purity organometallic iridium complex, which is one embodiment of the present invention, is described. Specifically, synthesis of bis[2-(6-phenyl-4-pyrimidinyl-κN3)phenyl-κC](2,4-pentanedionato-κ²O,O′)iridium(III) (abbreviation: [Ir(dppm)₂(acac)]), which is the organometallic iridium complex represented by Structural Formula (100) below, is described together with comparative examples in which an organometallic iridium complex containing an impurity such as a halogen is synthesized. A structure of [Ir(dppm)₂(acac)] is shown below.

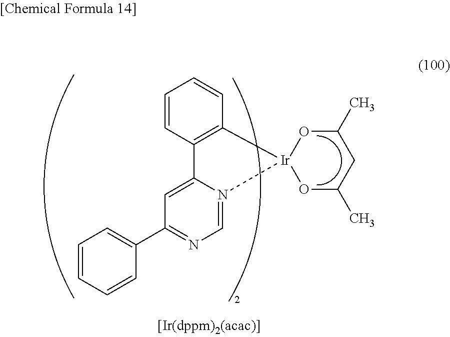

### Step 1: Synthesis of di-μ-chloro-tetrakis[2-(6-phenyl-4-pyrimidinyl-κN3)phenyl-κC]diiridium(III) (abbreviation: [Ir(dppm)₂Cl]₂)

First of all, the purity of 4,6-diphenylpyrimidine (abbreviation: Hdppm), which was a ligand used in Step 1, was examined using UPLC. The impurity of Hdppm was less than 0.1% by peak area count so that the purity of Hdppm was estimated to be 99.9%. In Step 1, such a high-purity ligand (Hdppm) was used.

In Step 1 of synthesis of the high-purity organometallic iridium complex that is one embodiment of the present invention, iridium content of iridium chloride hydrate is preferably greater than or equal to 51.00 mass % and less than 54.00 mass % (estimated iridium chloride as a trihydrate). Thus, the organometallic iridium complex was synthesized using Sample A whose iridium content was 53.55%. In the comparative examples, organometallic iridium complexes were synthesized using Sample B whose iridium content was 54.23% and Sample C whose iridium content was 50.4%. Furthermore, in the synthesis of the high-purity organometallic iridium complex that is one embodiment of the present invention, it is preferable to use the iridium chloride hydrate in which the atomic ratio of chlorine to iridium is greater than or equal to 2.5 and less than 3.1, further preferably greater than or equal to 2.5 and less than 3.0. The atomic ratio of chlorine to iridium was 2.9 in Sample A, 3.5 in comparative Sample B, and 3.1 in comparative Sample C. These ratios of chlorine to iridium were obtained according to normal procedure with an X-ray fluorescence spectrometer: the proportions of chlorine and iridium (the sum of detected major components is converted into 100%) were determined by each content of the major components (chlorine and iridium) estimated from florescent X-ray intensity with an X-ray fluorescence spectrometer (ZSX Primus II, manufactured by Rigaku Industrial Corporation). Note that the moisture is not detected. The conversion was performed on the assumption that no moisture was contained. Table 1 shows the obtained fluorescent X-ray intensity (unit: kcps), where a value in parentheses is the content (unit: mass %) estimated using the fluorescent X-ray intensity.

TABLE 1

| | Cl | Ir |
|---|---|---|
| Sample A | 146 (34.5) | 1829 (65.5) |
| Sample B | 184 (38.9) | 1898 (61.0) |
| Sample C | 149 (36.7) | 1698 (63.3) |

First, 15 mL of 2-ethoxyethanol, 5 mL of water, 1.61 g of the ligand (Hdppm), and 0.95 g of iridium chloride hydrate (Sample A, B, or C) were put into a recovery flask equipped with a reflux pipe and the air in the flask was replaced with argon. After that, irradiation with microwaves (2.45 GHz, 100 W) was performed for 1 hour to cause a reaction. The resulting mixture was suction-filtered using ethanol and washed with water and ethanol, so that a Binuclear complex [Ir(dppm)₂Cl]₂ as an abbreviation was obtained as a reddish brown powder. Note that the yield was 73% when Sample A was used, 76% when Sample B was used, and 73% when Sample C was used.

A synthesis scheme of Step 1 is shown in (a-1) below.

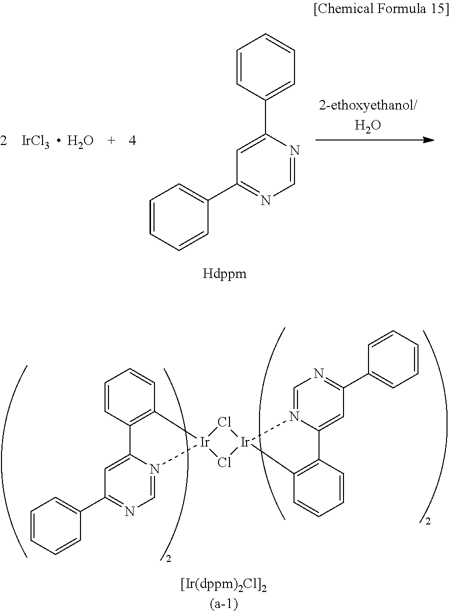

### Step 2: Synthesis of bis[2-(6-phenyl-4-pyrimidinyl-κN3)phenyl-κC](2,4-pentanedionato-κ²O,O′)iridium(III) (abbreviation: [Ir(dppm)₂(acac)]

Next, 20 mL of 2-ethoxyethanol, 1.60 g of the dinuclear complex [Ir(dppm)₂Cl]₂ obtained in Step 1 using one of Samples A to C, 0.36 g of 2,4-pentanedione (abbreviation: Hacac), and 1.30 g of sodium carbonate were put into a recovery flask equipped with a reflux pipe and the air in the flask was replaced with argon. Then, microwave irradiation (2.45 GHz, 100 W) was performed for 60 minutes. Furthermore, 0.36 g of Hacac was added, and irradiation with microwaves (2.45 GHz, 100 W) was performed again for 60 minutes so that heating was performed. The resulting mixture was suction-filtered using ethanol and washed with water and ethanol. The resulting residue was purified by silica gel column chromatography using dichloromethane and ethyl acetate in a ratio of 50:1 as a developing solvent, and recrystallized with a mixed solvent of dichloromethane and hexane; thus, [Ir(dppm)₂(acac)] was obtained as an orange powder. Note that the yield was 28% when Sample A was used in Step 1, 38% when Sample B was used in Step 1, and 44% when Sample C was used in Step 1.

A synthesis scheme of Step 2 is shown in (a-2) below.

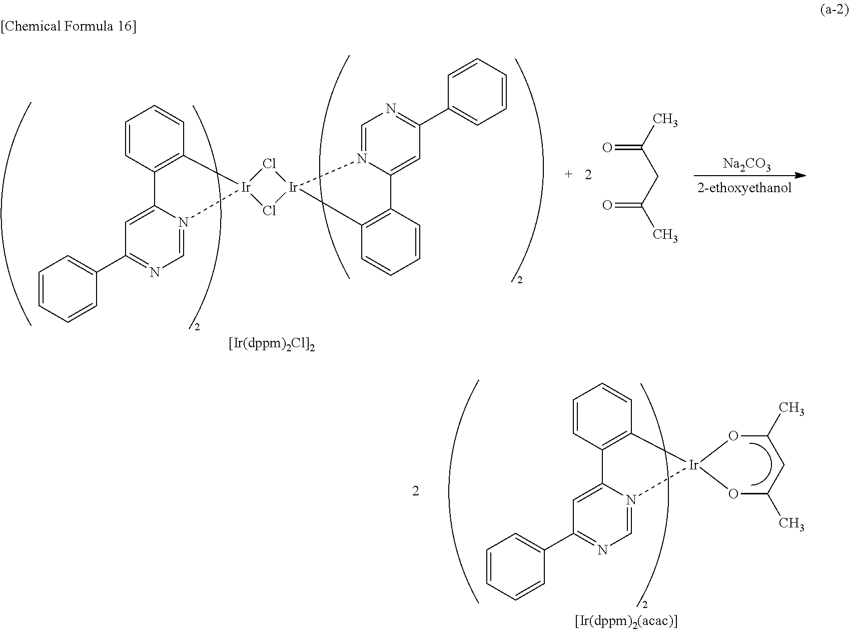

The three kinds of [Ir(dppm)₂(acac)] obtained in Step 2 using the respective samples were analyzed by nuclear magnetic resonance spectrometry (¹H-NMR), whereby the following results were obtained.

The results obtained when Sample A was used are as follows: ¹H-NMR. δ(CDCl₃): 1.83 (s, 6H), 5.30 (s, 1H), 6.48 (d, 2H), 6.82 (t, 2H), 6.91 (t, 2H), 7.56-7.62 (m, 6H), 7.78 (d, 2H), 8.18 (s, 2H), 8.25 (d, 4H), 9.17 (s, 2H).

The results obtained when Sample B was used are as follows: ¹H-NMR. δ(CDCl₃): 1.83 (s, 6H), 5.29 (s, 1H), 6.48 (d, 2H), 6.81 (t, 2H), 6.90 (t, 2H), 7.56-7.62 (m, 6H), 7.78 (d, 2H), 8.18 (s, 2H), 8.25 (d, 4H), 9.17 (s, 2H).

The results obtained when Sample C was used are as follows: ¹H-NMR. δ(CDCl₃): 1.84 (s, 6H), 5.30 (s, 1H), 6.48 (d, 2H), 6.81 (t, 2H), 6.91 (t, 2H), 7.56-7.62 (m, 6H), 7.78 (d, 2H), 8.18 (s, 2H), 8.25 (d, 4H), 9.17 (s, 2H).

It was shown that [Ir(dppm)₂(acac)], which was the organometallic complex represented by Structural Formula (100), was obtained with each of the above samples.

Next, the purity of the three kinds of [Ir(dppm)₂(acac)] (Structural Formula (100)) synthesized using the respective samples was analyzed using UPLC.

Purity test by peak area count showed that [Ir(dppm)₂(acac)] synthesized using Sample A included 0.1% impurity which was detected at m/z (mass-to-charge ratio)=804, and the purity of [Ir(dppm)₂(acac)] was 99.9%. It is thus shown that the use of iridium chloride hydrate (Sample A) in which the iridium content is 53.55% and the chlorine ratio is 2.9 as a raw material allows [Ir(dppm)₂(acac)] with high purity to be synthesized.

Purity test by peak area count showed that [Ir(dppm)₂(acac)] synthesized using Sample B included 0.5% impurity which was detected at m/z=789, and the purity of [Ir(dppm)₂(acac)] was 99.5%. Note that the impurity detected at m/z=789 is an ion including an isotope of chlorine; thus, [Ir(dppm)₂(acac)] synthesized using Sample B presumably contains a monochlorinated product as an impurity. This suggests that one of the ligands of [Ir(dppm)₂(acac)] is monochlorinated when [Ir(dppm)₂(acac)] is synthesized using iridium chloride hydrate (Sample B) with the 54.23% iridium content and the 3.5 atomic ratio of chlorine to iridium as a raw material. Note that it was difficult to remove the monochlorinated product by purification.

The purity test showed that [Ir(dppm)₂(acac)] synthesized using Sample C included the following impurities: m/z=972, 1012 (0.5%), m/z=789 (0.4%), note: m/z=971, 1012 with another retention time (0.1%). The purity was 98.7%. Note that the impurity detected at m/z=789 is an ion including an isotope of chlorine as described above; thus, which indicates that [Ir(dppm)₂(acac)] synthesized using Sample C contains a monochlorinated product as an impurity. This suggests that one of the ligands of [Ir(dppm)₂(acac)] is monochlorinated when [Ir(dppm)₂(acac)] is synthesized using iridium chloride hydrate (Sample C) with the 50.4% iridium content and the 3.1 atomic ratio of chlorine to iridium as a raw material. Note that it was difficult to remove the monochlorinated product by purification.

The organometallic iridium complexes were synthesized by the high-purity ligand (Hdppm) and the iridium chloride hydrate samples different in iridium content in this example. From the above-described results that one of the ligands of [Ir(dppm)₂(acac)], which had a high purity as a raw material, was monochlorinated, it can be concluded that chlorine in the iridium chloride hydrate is bonded to a highly reactive substitutable position of the ligand during the reaction in Step 1 illustrated in Synthesis Scheme (a-1), whereby the monochlorinated product is formed. It is conceivable that [Ir(dppm)₂(acac)] obtained by the synthesis accordingly contains an impurity which has a monochlorinated ligand.

As described above, by employing the synthesis method using Sample A, an impurity containing a product monosubstituted with a halogen (e.g., chlorine) was prevented from being generated and a high-purity organometallic iridium complex was synthesized in Example 1.

### EXAMPLE 2

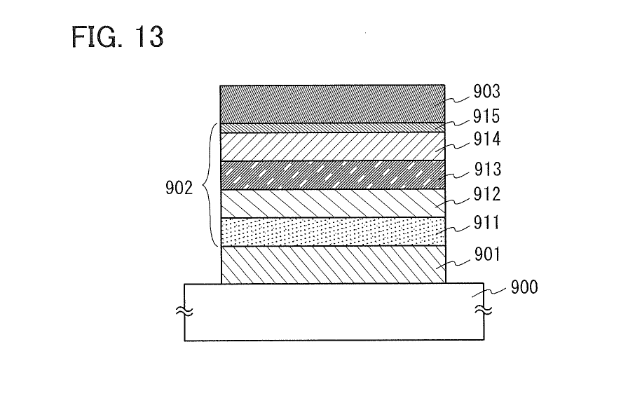

In Example 2, Light-emitting Element 1, Comparative Light-emitting Element 2, and Comparative Light-emitting Element 3 were fabricated and their element characteristics were compared. Light-emitting Element 1 is one embodiment of the present invention and includes the high-purity organometallic iridium complex [Ir(dppm)₂(acac)] (Structural Formula (100)) in a light-emitting layer. Comparative Light-emitting Element 2 and Comparative Light-emitting Element 3 include, in light-emitting layers, the respective kinds of organometallic iridium complexes [Ir(dppm)₂(acac)] (Structural Formula (100)) each of which contains a halogen as an impurity. Note that the fabrication of Light-emitting Element 1 and Comparative Light-emitting Elements 2 and 3 is described with reference to FIG. 13. Chemical formulae of materials used in this example are shown below.

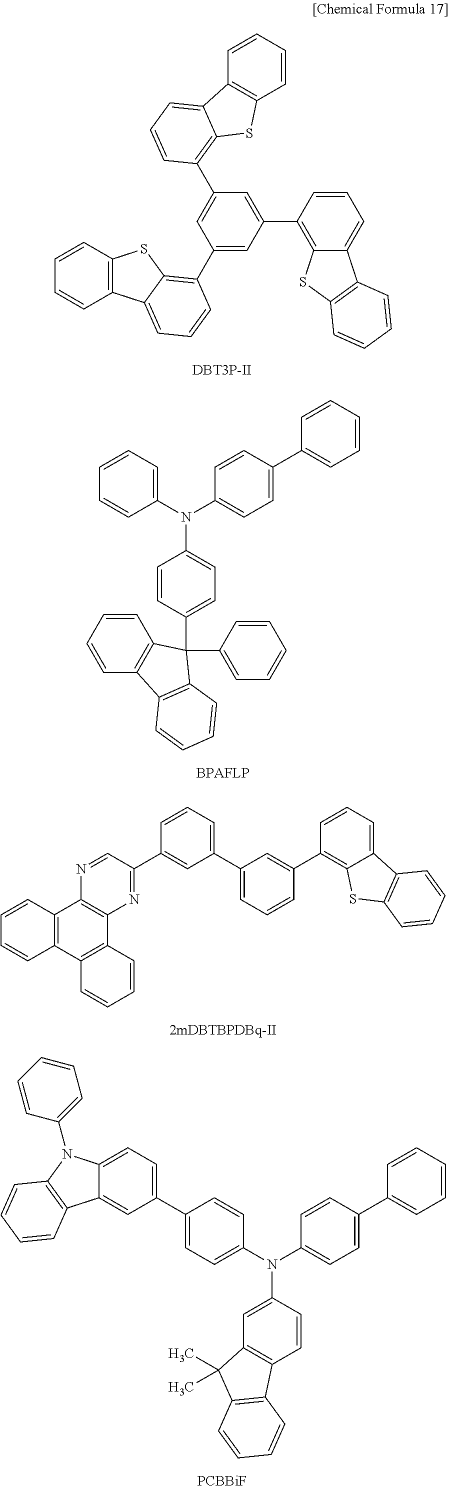

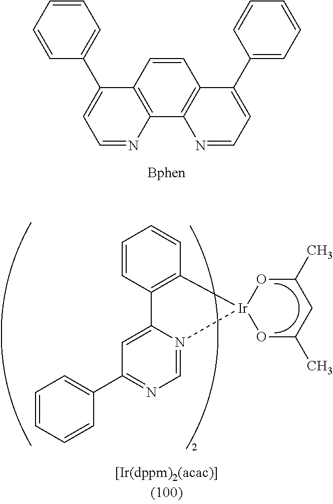

### <<Fabrication of Light-Emitting Element 1, Comparative Light-Emitting Element 2, and Comparative Light-Emitting Element 3>>

First, indium tin oxide containing silicon oxide (ITSO) was deposited over a glass substrate 900 by a sputtering method, whereby a first electrode 901 functioning as an anode was formed. Note that the thickness was set to 110 nm and the electrode area was set to 2 mm×2 mm.

Next, for pretreatment before fabricating Light-emitting Elements 1 to 3 over the substrate 900, a surface of the substrate was washed with water, baking was performed at 200° C. for 1 hour, and then UV ozone treatment was performed for 370 seconds.

After that, the substrate was transferred into a vacuum evaporation apparatus where the pressure had been reduced to approximately 10⁻⁴ Pa, and subjected to vacuum baking at 170° C. for 30 minutes in a heating chamber of the vacuum evaporation apparatus, and then the substrate 900 was cooled down for approximately 30 minutes.

Next, the substrate 900 was fixed to a holder provided in the vacuum evaporation apparatus so that a surface of the substrate over which the first electrode 901 was formed faced downward. In this example, a case is described in which a hole-injection layer 911, a hole-transport layer 912, a light-emitting layer 913, an electron-transport layer 914, and an electron-injection layer 915, which are included in an EL layer 902, are sequentially formed by a vacuum evaporation method.

After reducing the pressure in the vacuum evaporation apparatus to 10⁻⁴ Pa, 1,3,5-tri(dibenzothiophen-4-yl)benzene (abbreviation: DBT3P-II) and molybdenum oxide were deposited by co-evaporation so that the mass ratio of DBT3P-II to molybdenum oxide was 4:2, whereby the hole-injection layer 911 was formed over the first electrode 901. The thickness of the hole-injection layer 911 was set to 20 nm. Note that co-evaporation is an evaporation method in which a plurality of different substances are concurrently vaporized from different evaporation sources.

Next, 4-phenyl-4′-(9-phenylfluoren-9-yl)triphenylamine (abbreviation: BPAFLP) was deposited by evaporation to a thickness of 20 nm, whereby the hole-transport layer 912 was formed.

Next, the light-emitting layer 913 was formed over the hole-transport layer 912 in the following manner: 2-[3′-(dibenzothiophen-4-yl)biphenyl-3-yl]dibenzo[f,h]quinoxaline (abbreviation: 2mDBTBPDBq-II), N-(1,1′-biphenyl-4-yl)-9,9-dimethyl-N-[4-(9-phenyl-9H-carbazol-3-yl)phenyl]-9H-fluoren-2-amine (abbreviation: PCBBiF), and [Ir(dppm)₂(acac)] were deposited by co-evaporation to a thickness of 20 nm with a mass ratio of 2mDBTBPDBq-II to PCBBiF to [Ir(dppm)₂(acac)] being 0.7:0.3:0.05; then, 2mDBTBPDBq-II, PCBBiF, and [Ir(dppm)₂(acac)] were deposited by co-evaporation to a thickness of 20 nm with a mass ratio of 2mDBTBPDBq-II to PCBBiF to [Ir(dppm)₂(acac)] being 0.8:0.2:0.01. Thus, the thickness of the light-emitting layer 913 was 40 nm. For the formation of the light-emitting layer, [Ir(dppm)₂(acac)] synthesized using Sample A was used in Light-emitting Element 1, [Ir(dppm)₂(acac)] synthesized using Sample B was used in Comparative Light-emitting Element 2, and [Ir(dppm)₂(acac)] synthesized using Sample C was used in Comparative Light-emitting Element 3.

Next, the electron-transport layer 914 was formed in such a manner that 2mDBTBPDBq-II was deposited by evaporation over the light-emitting layer 913 to a thickness of 20 nm and then bathophenanthroline (abbreviation: Bphen) was deposited by evaporation to a thickness of 10 nm. Furthermore, lithium fluoride was deposited by evaporation to a thickness of 1 nm over the electron-transport layer 914, whereby the electron-injection layer 915 was formed.

Finally, aluminum was deposited by evaporation to a thickness of 200 nm over the electron-injection layer 915, whereby a second electrode 903 functioning as a cathode was formed. Through the above-described steps, Light-emitting Element 1 and Comparative Light-emitting Elements 2 and 3 were fabricated. Note that in all the above evaporation steps, evaporation was performed by a resistance-heating method.

Table 2 shows the element structures of Light-emitting Element 1 and Comparative Light-emitting Elements 2 and 3 fabricated as described above.

TABLE 2

| | | | Hole- | Light- | | | Electron- | |
|---|---|---|---|---|---|---|---|---|
| | First | Hole-injection | transport | emitting | | | injection | Second |
| | electrode | layer | layer | layer | Electron-transport layer | | layer | electrode |
| Light-emitting | ITSO | DBT3P-II:MoOₓ | BPAFLP | *^{A} | 2mDBTBPDBq-II | Bphen | LiF | Al |
| Element 1 | (110 nm) | (4:2 20 nm) | (20 nm) | | (20 nm) | (10 nm) | (1 nm) | (200 nm) |
| Comparative | ITSO | DBT3P-II:MoOₓ | BPAFLP | *^{B} | 2mDBTBPDBq-II | Bphen | LiF | Al |
| Light-emitting | (110 nm) | (4:2 20 nm) | (20 nm) | | (20 nm) | (10 nm) | (1 nm) | (200 nm) |
| Element 2 | | | | | | | | |
| Comparative | ITSO | DBT3P-II:MoOₓ | BPAFLP | *^{C} | 2mDBTBPDBq-II | Bphen | LiF | Al |
| Light-emitting | (110 nm) | (4:2 20 nm) | (20 nm) | | (20 nm) | (10 nm) | (1 nm) | (200 nm) |
| Element 3 | | | | | | | | |

*^{A} 2mDBTBPDBq-II: PCBBiF: [Ir(dppm)₂(acac)] (Sample A) (0.7:0.3:0.05 20 nm\0.8:0.2:0.05 20 nm)
*^{B} 2mDBTBPDBq-II: PCBBiF: [Ir(dppm)₂(acac)] (Sample B) (0.7:0.3:0.05 20 nm\0.8:0.2:0.05 20 nm)
*^{C} 2mDBTBPDBq-II: PCBBiF: [Ir(dppm)₂(acac)] (Sample C) (0.7:0.3:0.05 20 nm\0.8:0.2:0.05 20 nm)

Light-emitting Element 1 and Comparative Light-emitting Elements 2 and 3 fabricated were sealed in a glove box under a nitrogen atmosphere so as not to be exposed to the air (a sealant was applied to surround the element, and at the time of sealing, UV treatment was performed and heat treatment was perfoiiiied at 80° C. for 1 hour).

### <<Operation Characteristics of Light-Emitting Element 1 and Comparative Light-Emitting Elements 2 and 3>>

Operation characteristics of Light-emitting Element 1 and Comparative Light-emitting Elements 2 and 3 fabricated were measured. Note that the measurement was carried out at room temperature (in an atmosphere kept at 25° C.).

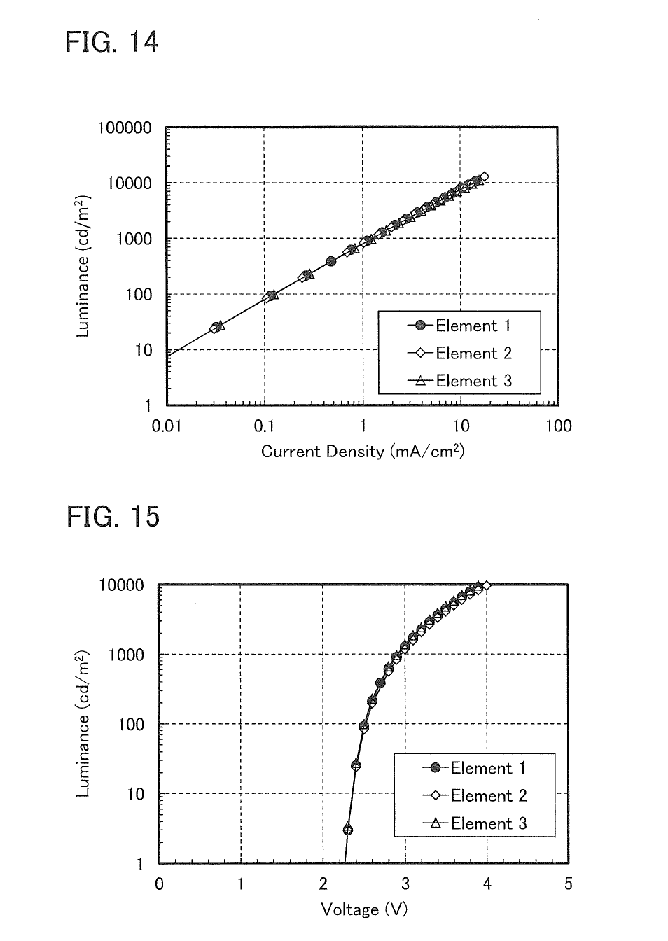

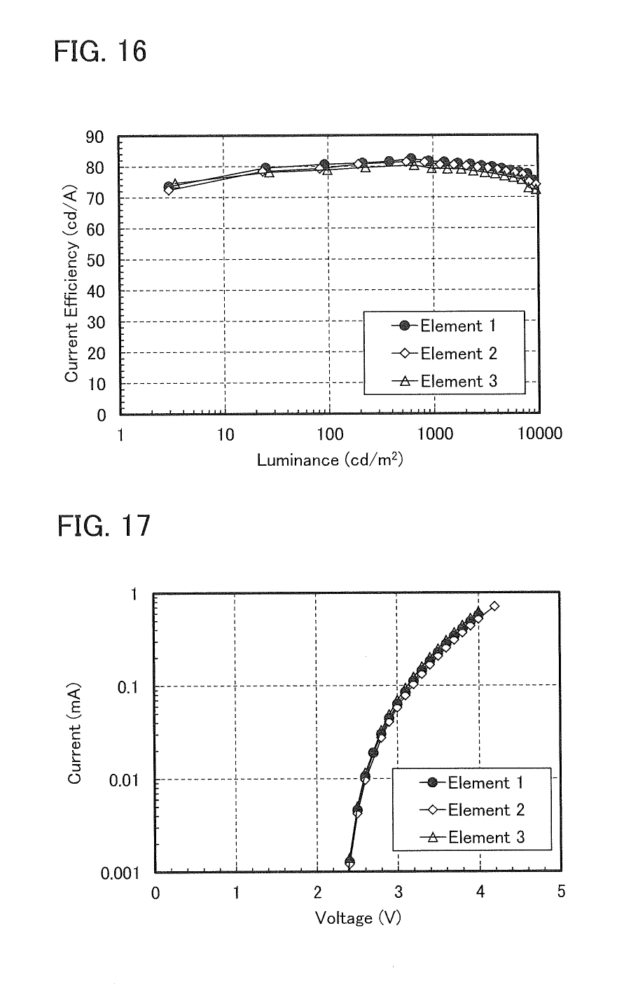

FIG. 14 shows current density-luminance characteristics of the above light-emitting elements, FIG. 15 shows voltage-luminance characteristics of the above light-emitting elements, FIG. 16 shows luminance-current efficiency characteristics of the above light-emitting elements, and FIG. 17 shows voltage-current characteristics of the above light-emitting elements.

These results reveal that Comparative Light-emitting Elements 2 and 3 that were fabricated using the respective kinds of organometallic iridium complexes each of which contains a halogen as an impurity have efficiency as high as that of Light-emitting Element 1 of one embodiment of the present invention that was fabricated using the high-purity organometallic iridium complex in the light-emitting layer. Table 3 shows initial values of main characteristics of Light-emitting Element 1 and Comparative Light-emitting Elements 2 and 3 at a luminance of approximately 1000 cd/m².

TABLE 3

| | | | | | | | | External |
|---|---|---|---|---|---|---|---|---|
| | | | Current | | | Current | Power | quantum |
| | Voltage | Current | density | Chromaticity | Luminance | efficiency | efficiency | efficiency |
| | (V) | (mA) | (mA/cm²) | (x, y) | (cd/m²) | (cd/A) | (lm/W) | (%) |
| Light-emitting | 2.9 | 0.045 | 1.1 | (0.55, 0.45) | 910 | 82 | 88 | 30 |
| Element 1 | | | | | | | | |
| Comparative | 2.9 | 0.041 | 1 | (0.55, 0.44) | 830 | 81 | 88 | 31 |
| Light-emitting | | | | | | | | |
| Element 2 | | | | | | | | |
| Comparative | 2.9 | 0.049 | 1.2 | (0.56, 0.44) | 970 | 79 | 86 | 30 |
| Light-emitting | | | | | | | | |
| Element 3 | | | | | | | | |

The results in the above table show that Light-emitting Element 1 and Comparative Light-emitting Elements 2 and 3 fabricated in this example are light-emitting elements having high luminance and high current efficiency. In other words, the light-emitting elements with low drive voltage were obtained. Moreover, as for color purity, the light-emitting elements exhibit yellow light emission with excellent color purity.

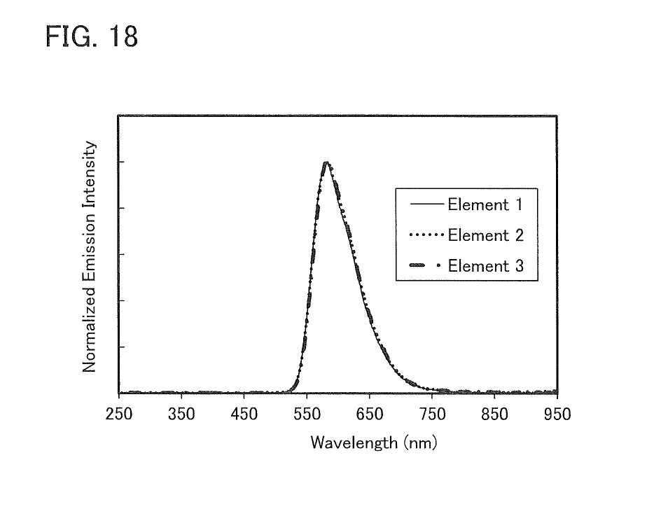

FIG. 18 shows emission spectra of Light-emitting Element 1 and Comparative Light-emitting Elements 2 and 3 to which current was applied at a current density of 25 mA/cm². As shown in FIG. 18, the emission spectra of Light-emitting Element 1 and Comparative Light-emitting Elements 2 and 3 each have a peak at around 586 nm and it is suggested that the peak is derived from emission of the organometallic iridium complex used in the light-emitting layer of each light-emitting element, [Ir(dppm)₂(acac)].

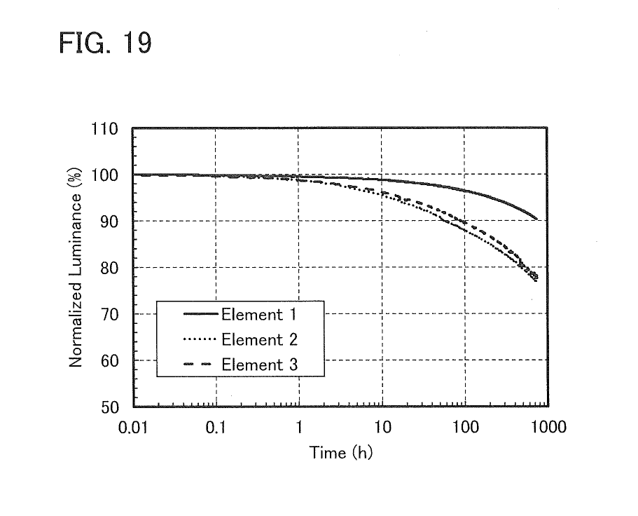

FIG. 19 shows results of reliability tests of Light-emitting Element 1 and Comparative Light-emitting Elements 2 and 3. In FIG. 19, the vertical axis represents normalized luminance (%) with an initial luminance of 100% and the horizontal axis represents driving time (h) of the light-emitting elements. Note that in the reliability tests, Light-emitting Element 1 and Comparative Light-emitting Elements 2 and 3 were driven under the conditions where the initial luminance was set to 5000 cd/m² and the current density was constant.

The results reveal that Light-emitting Element 1 of one embodiment of the present invention that was fabricated using the high-purity organometallic iridium complex in the light-emitting layer is a light-emitting element that has a longer lifetime and higher reliability than Comparative Light-emitting Elements 2 and 3 fabricated using the respective kinds of organometallic iridium complexes each of which contains a halogen as an impurity.

### EXAMPLE 3

### SYNTHESIS EXAMPLE 2

In Example 2, a synthesis method of a high-purity organometallic iridium complex, which is one embodiment of the present invention, is described. Specifically, synthesis of tris[2-(1H-pyrazol-1-yl-κN2)phenyl-κC] iridium(III) (abbreviation: [Ir(ppz)₃]), which is the organometallic iridium complex represented by Structural Formula (200) below, is described together with a comparative example in which an organometallic iridium complex containing an impurity such as a halogen is synthesized. A structure of [Ir(ppz)₃] is shown below.

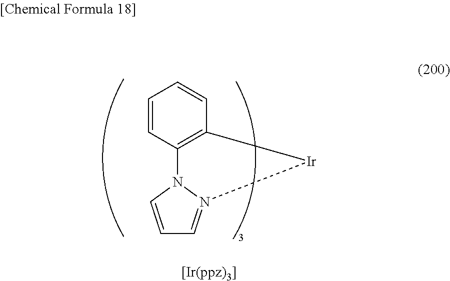

### Step 1: Synthesis of di-μ-chloro-tetrakis[2-(1H-pyrazol-1-yl-κN2)phenyl-κC]diiridium(III) (abbreviation: [Ir(ppz)₂Cl]₂)

First of all, the purity of 1-phenylpyrazole (abbreviation: Hppz), which was a ligand used in Steps 1 and 2, was examined using UPLC. The peak area count of an impurity was less than 0.1%, so that the purity was estimated to be 99.9%. In Steps 1 and 2, such a high-purity ligand (Hppz) was used.

### [Step 1-1]

First, a synthesis example in which Sample A was used is described. Into a round-bottom flask equipped with a reflux pipe were put 30 mL of 2-ethoxyethanol, 10 mL of water, 2.5 g of the ligand (Hppz), and 2.5 g of iridium chloride hydrate (Sample A), and the air in the flask was replaced with argon. Then, microwave irradiation (2.45 GHz, 100 W) was performed for 1.5 hours to cause a reaction. The resulting mixture was suction-filtered using ethanol and washed with water and ethanol, so that a dinuclear complex [Ir(ppz)₂Cl]₂ was obtained as a white powder. The yield was 76%.

### [Step 1-2]

Next, a synthesis example in which Sample B was used is described. Into a round-bottom flask equipped with a reflux pipe were put 30 mL of 2-ethoxyethanol, 10 mL of water, 5.0 g of the ligand (Hppz), 4.9 g of iridium chloride hydrate (Sample B), and the air in the flask was replaced with argon. Then, microwave irradiation (2.45 GHz, 100 W) was performed for 3 hours to cause a reaction. The resulting mixture was suction-filtered using ethanol and washed with water and ethanol, so that the dinuclear complex [Ir(ppz)₂Cl]₂ was obtained as a white powder. The yield was 80%.

A synthesis scheme of Step 1 is shown in (b-1) below.

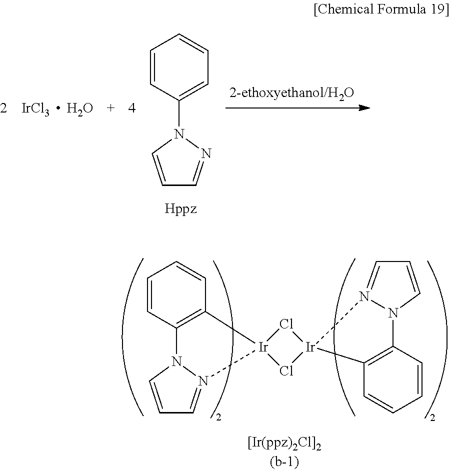

### Step 2: Synthesis of tris[2-(1H-pyrazol-1-yl-κN2)phenyl-κC]iridium(III) (abbreviation: [Ir(ppz)₃])

### [Step 2-1]

Into a 200-ml three-neck flask were put 3.4 g of the dinuclear complex [Ir(ppz)₂Cl]₂ obtained in Step 1-1, 1.4 g of the ligand (Hppz), 4.6 g of potassium carbonate, and 30 g of phenol, and heating was performed at 200° C. under a nitrogen stream for 20 hours. Methanol was added to the reaction mixture, and the mixture was irradiated with ultrasonic waves and then suction-filtered to give a white solid. The obtained solid was washed with water and methanol. The resulting solid was recrystallized with ethyl acetate; thus, [Ir(ppz)₃] was obtained as a white powder in a yield of 48%.

### [Step 2-2]

Into a 200-ml three-neck flask were put 6.8 g of the dinuclear complex [Ir(ppz)₂Cl]₂ obtained in Step 1-2, 2.8 g of the ligand (Hppz), 9.1 g of potassium carbonate, and 60 g of phenol, and heating was performed at 200° C. under a nitrogen stream for 19 hours. Methanol was added to the reaction mixture, and the mixture was irradiated with ultrasonic waves and then suction-filtered to give a white solid. The obtained solid was washed with water and methanol. The resulting solid was recrystallized with ethyl acetate; thus, [Ir(ppz)₃] was obtained as a white powder in a yield of 80%.

A synthesis scheme of Step 2 is shown in (b-2) below.

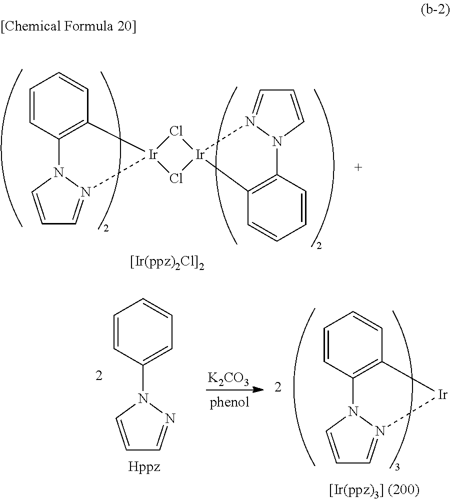

The two kinds of [Ir(ppz)₃] obtained in Step 2 were analyzed by nuclear magnetic resonance spectrometry (¹H-NMR), whereby the following results were obtained.

The results obtained when Sample A was used are as follows: ¹H-NMR. δ(CDCl₃): 6.38 (t, 3H), 6.79 (t, 3H), 6.85 (d, 3H), 6.92 (t, 3H), 6.98 (d, 3H), 7.20 (d, 3H), 7.97 (d, 3H).

The results obtained when Sample B was used are as follows: ¹H-NMR. δ(CDCl₃): 6.39 (t, 3H), 6.78 (t, 3H), 6.85 (d, 3H), 6.92 (t, 3H), 6.99 (d, 3H), 7.20 (d, 3H), 7.98 (d, 3H).

It was shown that [Ir(ppz)₃], which was the organometallic complex represented by Structural Formula (200), was obtained with each of the above samples.

Next, the purity of the two kinds of [Ir(ppz)₃] synthesized using the respective samples was analyzed using UPLC.

The analysis of [Ir(ppz)₃] synthesized using Sample A showed that a peak was not detected at m/z (mass-to-charge ratio) that indicates an impurity, so that the purity of [Ir(ppz)₃] was estimated to be 99.9% or more. It is thus shown that [Ir(ppz)₃] has high purity when it is synthesized by iridium chloride hydrate with the 53.55% iridium content and the 2.9 atomic ratio of chlorine to iridium (Sample A) as a raw material.

Purity test by peak area count showed that [Ir(ppz)₃] synthesized using Sample B included the following impurities: m/z=637 (0.1%), m/z=656 (0.1%). The purity of [Ir(ppz)₃] was 99.8%. Note that the impurity detected at m/z=656 is an ion including an isotope of chlorine, which indicates that [Ir(ppz)₃] synthesized using Sample B contains a monochlorinated product as an impurity. This suggests that one of the ligands of [Ir(ppz)₃] becomes a monochlorinated product when [Ir(ppz)₃] is synthesized using iridium chloride hydrate (Sample B) in which the iridium content is 54.23% and the atomic ratio of chlorine to iridium is 3.5 as a raw material. Note that it was difficult to remove the monochlorinated product by purification.

It is thus presumable that during the reaction in Step 1 illustrated in Synthesis Scheme (b-1) of the synthesis of [Ir(ppz)₃] using iridium chloride hydrate and the high-purity ligand (Hppz), chlorine of the iridium chloride hydrate is bonded to a highly reactive substitutable position of the ligand, whereby the monochlorinated product is formed. It is conceivable that [Ir(ppz)₃] obtained by the synthesis accordingly contains an impurity which has a monochlorinated ligand.

Then, to measure the concentration of a halogen element contained in the two kinds of [Ir(ppz)₃] samples synthesized using the above samples, quantitative determination of chlorine was performed by combustion-ion chromatography. Note that the samples were synthesized without using a chlorinated solvent; therefore, it is probably possible to examine the content of chlorine that is contained through monochiorination of one of the ligands of [Ir(ppz)₃] during the synthesis of [Ir(ppz)₃].

As a result, 1 ppm of chlorine was detected in [Ir(ppz)₃] synthesized using Sample A and 95 ppm of chlorine was detected in [Ir(ppz)₃] synthesized using Sample B. It was thus shown that [Ir(ppz)₃] with high purity was obtained by being synthesized with the use of iridium chloride hydrate with the 53.55% iridium content and the 2.9 atomic ratio of chlorine to iridium as a raw material. Note that Sample A is included in the iridium chloride hydrate in which the ratio of iridium to chlorine is 1 to greater than or equal to 2.5 and less than 3.1, preferably 1 to greater than or equal to 2.5 and less than 3.0. In contrast, it was found that [Ir(ppz)₃] containing chlorine was synthesized in the case where iridium chloride hydrate with the 54.23% iridium content and the 3.5 atomic ratio of chlorine to iridium was used as a raw material.

As described above, in Example 3, production of an impurity, namely an organometallic iridium complex containing a ligand monosubstituted with a halogen (e.g., chlorine) was prevented, and a high-purity organometallic iridium complex was synthesized by the synthesis method using Sample A.

This application is based on Japanese Patent Application serial no. 2014-219055 filed with Japan Patent Office on Oct. 28, 2014 and Japanese Patent Application serial no. 2014-264848 filed with Japan Patent Office on Dec. 26, 2014, the entire contents of which are hereby incorporated by reference.

What is claimed is:

1. A synthesis method of an organometallic iridium complex,
reacting a compound and iridium chloride,
wherein an atomic ratio of chlorine to iridium in the iridium chloride is greater than or equal to 2.5 and less than 3.1.

2. The synthesis method according to claim 1, wherein the atomic ratio of chlorine to iridium in the iridium chloride is greater than or equal to 2.5 and less than 3.0.

3. The synthesis method according to claim 1, wherein the atomic ratio of chlorine to iridium is measured with an X-ray fluorescence spectrometer.

4. The synthesis method according to claim 1,
wherein reacting the compound and the iridium chloride produces an immediate compound,
wherein the immediate compound comprises two iridium atoms and two chloride atoms which each bond to the two iridium atoms, and
wherein the synthesis method further comprises a step of producing the organometallic iridium complex by using the immediate compound.

5. The synthesis method according to claim 1,
wherein the organometallic iridium complex comprises an impurity detected by high performance liquid chromatography,
wherein the impurity has a chlorine-substituted structure of the organometallic iridium complex.

6. The synthesis method according to claim 5, wherein the impurity has a chlorine-monosubstituted structure of the organometallic iridium complex.

7. The synthesis method according to claim 1,
wherein the organometallic iridium complex comprises an impurity, and
wherein a concentration of chlorine in the organometallic iridium complex has a value greater than or equal to 1 and less than 95 as a unit of ppm.

8. The synthesis method according to claim 1, wherein the iridium chloride is iridium chloride hydrate.

9. The synthesis method according to claim 1, wherein the iridium chloride has phosphorescence in the room temperature.

10. A synthesis method of an organometallic iridium complex,
reacting a first compound and iridium chloride to obtain an intermediate compound,
heating the intermediate compound to obtain the organometallic iridium complex,
wherein the first compound has a first ring and a second ring,
wherein the first ring and the second ring is bonded to each other,
wherein the second ring comprises a nitrogen-substituted benzene ring,
wherein the substituted position of the nitrogen atom in the second ring is an ortho-position,
wherein the intermediate compound has a bond between an iridium atom and the nitrogen atom in the second ring and a bond between the iridium atom and the first ring, and
wherein an atomic ratio of chlorine to iridium in the iridium chloride is greater than or equal to 2.5 and less than 3.1.

11. The synthesis method according to claim 10, wherein the iridium chloride is iridium chloride hydrate.

12. The synthesis method according to claim 11,
wherein reacting the first compound and the iridium chloride is represented by the following Scheme (A-1): 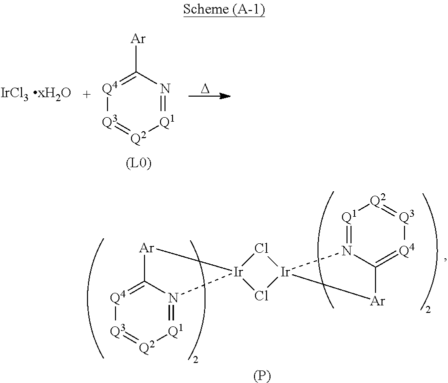
wherein (L0) represents the first compound in Scheme (A-1),
wherein (P) represents the intermediate compound in Scheme (A-1), and
wherein:
at least one of Q¹ to Q⁴ is a nitrogen atom, and each of the others is a carbon atom bonded to a substituent or hydrogen; and
Ar represents a substituted or unsubstituted arylene group having 6 to 10 carbon atoms.

13. The synthesis method according to claim 12,
wherein heating the intermediate compound is performed after adding a second compound,
wherein heating the intermediate compound is represented by the following Scheme (A-2): 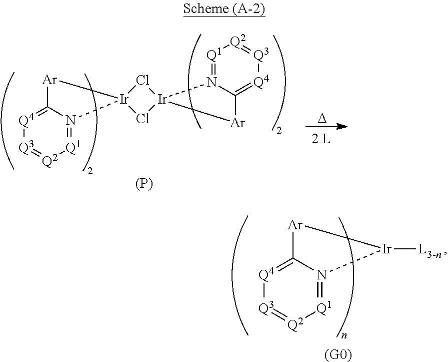
wherein the second compound is represented by L in Scheme (A-2),
wherein the organometallic iridium complex is represented by (G0), and
wherein:
n represents 2; and
L in (G0) represents a monoanionic ligand.

14. The synthesis method according to claim 12,
wherein heating the intermediate compound is represented by the following Scheme (A-2): 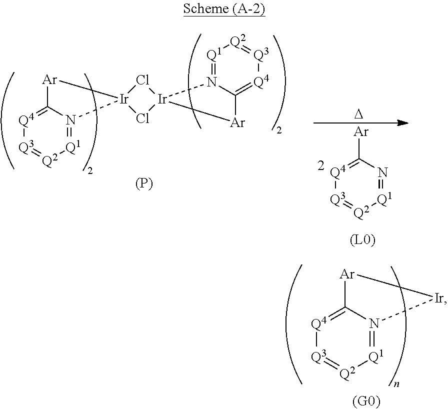
wherein the organometallic iridium complex is represented by (G0), and
wherein n represents 3.

15. The synthesis method according to claim 12, wherein the atomic ratio of chlorine to iridium in the iridium chloride is greater than or equal to 2.5 and less than 3.0.

16. The synthesis method according to claim 12, wherein the atomic ratio of chlorine to iridium is measured with an X-ray fluorescence spectrometer.

17. The synthesis method according to claim 12,
wherein the organometallic iridium complex comprises an impurity detected by high performance liquid chromatography,
wherein the impurity has a chlorine-substituted structure of the organometallic iridium complex.

18. The synthesis method according to claim 17, wherein the impurity has a chlorine-monosubstituted structure of the organometallic iridium complex.

19. The synthesis method according to claim 12, wherein the organometallic iridium complex comprises an impurity,
wherein a concentration of chlorine in the organometallic iridium complex has a value greater than or equal to 1 and less than 95 as a unit of ppm.

20. The synthesis method according to claim 10, wherein the iridium chloride has phosphorescence in the room temperature.
